(19) United States
(12) Patent Application Publication
(10) Pub. No.: US 2026/0226346 A1
(43) Pub. Date: Aug. 6, 2026

(54) DEFECT-FREE PEROVSKITE NANOCRYSTAL, METHOD OF MANUFACTURING SAME, AND LIGHT-EMITTING DEVICE INCLUDING SAME

(71) Applicant: The Industry & Academic Cooperation in Chungnam National University (IAC), Daejeon (KR)

(72) Inventors: Jihoon CHOI, Daejeon (KR); Min-Gi JEON, Daejeon (KR)

(73) Assignee: The Industry & Academic Cooperation in Chungnam National University (IAC), Daejeon (KR)

(21) Appl. No.: 19/244,174

(22) Filed: Jun. 20, 2025

(30) Foreign Application Priority Data
Feb. 6, 2025 (KR) 10-2025-0015181

(51) Int. Cl. C09K 11/66; B82Y 20/00; B82Y 40/00; H10K 50/115

(52) U.S. Cl. CPC C09K 11/665; B82Y 20/00; B82Y 40/00; H10K 50/115

(57) ABSTRACT

Proposed herein are a defect-free perovskite nanocrystal, including CsPbX₃ (wherein X is a halogen) perovskite nanocrystal whose surface is modified with BF₄⁻ anions, a method of manufacturing the same, and a light-emitting device comprising the same, wherein the perovskite nanocrystal treated with nitrosonium tetrafluoroborate (NOBF₄) has reduced surface defects due to a binding of BF₄⁻ anions in place of long organic ligands, thereby exhibiting significantly improved thermal and optical stability.

### CROSS REFERENCE TO RELATED APPLICATION

The present application claims priority to Korean Patent Applications No. 10-2025-0015181, filed Feb. 6, 2025, the entire contents of which are incorporated herein for all purposes by this reference.

### BACKGROUND OF THE DISCLOSURE

### Field of the Disclosure

The present disclosure relates to a defect-free perovskite nanocrystal, a method of manufacturing the same, and a light-emitting device including the same.

### Description of the Related Art

A metal halide perovskite nanocrystal (PNC) is promising candidate for high-performance light-emitting diodes (LEDs) due to its broad color gamut, high color purity, high photoluminescence quantum efficiency (PLQY), and low cost solution processability.

One of attractive features of PNC is spatially trapping excitons within the nanocrystal (NC) to enhance optoelectronic properties related to a radiative recombination. However, an inherent limitation of these low-dimensional materials is a formation of uncontrolled surface defects during a film fabrication process due to fast attachment-detachment kinetics of surface capping molecules. In a presence of a high density of surface defects, the imperfections of a NC surface can form additional electrons or hole trap centers, and defect bands, leading to undesired emission characteristics. Therefore, a surface chemistry and a structure of the PNC play a key role in determining an optoelectronic properties associated with a charge transport in LEDs, and a radiative recombination of charge carriers.

Based on ligand exchange reactions using L-type (neutral) or Z-type (polar) ligands with functional groups (e.g., amines, sulfides, phosphates, thiols, halides), there have been various strategies to suppress surface defects. Among them, fluorinated carbon ligands, or Z-type ligands containing fluorine anions, have received great attention because fluorine is the most electronegative element, and is expected to promote strong interactions on a PNC surface.

For example, Non-Patent Reference 1 reported that after certain treatments, a surface bromine deficiency of CsPbBr₃ NC was partially compensated, and replacing bromine anions with fluorine anions suppressed a thermal quenching of luminescence at temperatures up to 373K. Non-patent reference 2 demonstrated that trifluoroacetate anions (CF₃COO⁻) effectively passivated surface defects, and improve a crystallization rate of perovskite films.

On the other hand, non-patent reference 3 recently reported that when 1-butyl-3-methylimidazolium tetrafluoroborate ionic liquid is used as an additive for polycrystalline perovskite layers, BF₄⁻ ions did not contribute to defect passivation in green-emitting perovskite LEDs. These studies show that fluorine-containing functional groups, which have stronger electron attraction property than that of other anions, can provide many advantages for efficient radiative recombination on the surface of a metal halide PNC.

However, in a process of purifying PNC for optoelectronic devices, excess ligands are typically removed from a PNC surface by precipitation washing procedures to facilitate a charge transfer through a PNC layer. In particular, polar solvents such as methyl and ethyl acetate have been widely used to lower a dynamic barrier for ligand desorption and exchange.

However, this can lead to severe desorption of bound ligands, conformational changes, and subsequent non-reversible aggregation, and luminescence quenching. Recently, non-patent reference 4 reported that a reactivity of neutral and polar ligands with CsPbBr₃ NCs can be controlled in acidic or basic environments. For example, it was observed that as an acidity of a ligand used for treatment increased, more corrosion of a CsPbBr₃ surface occurred (e.g., from a pKa of 9.9 for oleic acid to a pKa of −1.8 for dodecylbenzenesulfonic acid). Similarly, nitrosonium tetrafluoroborate (NOBF₄) has been used to remove bound ligands from II-VI and III-V semiconductor quantum dots, wherein NO⁺ cations easily form nitrous (pKa=3.4), and fluoroboric acid (pKa=−0.4), providing a relatively acidic environment. Therefore, an introduction of BF₄⁻ anions along with several cations such as MA⁺, H⁺, and NO⁺ is expected to significantly reduce a defect density of the PNC surface for a reconstructed crystal lattice, and precisely control a surface termination suitable for subsequent ligand exchange processes. However, utilization, and properties of BF₄⁻ treated CsPbBr₃ LEDs are still not fully understood, BF₄⁻ being important for controlling a surface chemistry associated with surface defects of the CsPbBr₃ NC.

### RELATED ART DOCUMENTS

### Non-Patent References:

(Non-patent reference 1) Suppression of Temperature Quenching in Perovskite Nanocrystal for Efficient and Thermally Stable Light-Emitting Diodes. Nat. Photonics 2021, 15 (5), 379-385.
(Non-patent reference 2) Trifluoroacetate Induced Small-Grained CsPbBr₃ Perovskite Films Result in Efficient and Stable Light-Emitting Devices. Nat Commun 2019, 10 (1), 665.
(Non-patent reference 3) Targeted Distribution of Passivator for Polycrystalline Perovskite Light-Emitting Diodes with High Efficiency. ACS Energy Lett. 2021, 6 (12), 4187-4194.
(Non-patent reference 4) The Reactivity of CsPbBr₃ Nanocrystal toward Acid/Base Ligands. ACS Nano 2022, 16 (1), 1444-1455.

### SUMMARY OF THE DISCLOSURE

Accordingly, the present disclosure has been made keeping in mind the above problems occurring in the related art, and an objective of the present disclosure is to provide a defect-free perovskite nanocrystal, a method of manufacturing the same, and a light-emitting device including the same.

However, the above mentioned object is just illustrative, and technical spirit of the present disclosure is not limited thereto.

One aspect of the present disclosure to achieve the above object relates to a defect-free perovskite nanocrystal, including a CsPbX₃ (wherein X is a halogen) perovskite nanocrystal whose surface is modified with BF₄⁻ anions.

More preferably, the defect-free perovskite nanocrystal may be characterized by having a space group Pbnm which is found in the X-ray diffraction (XRD) pattern, and satisfying the following equations 1 to 3:

$$8.1 \leq a \leq 8.3 Å \qquad [ Equation 1 ]$$

$$8.15 \leq b \leq 8.35 Å \qquad [ Equation 2 ]$$

$$11.6 \leq c \leq 11.9 Å , \qquad [ Equation 3 ]$$

wherein in the Equations 1 through 3,
a, b, and c each represent a lattice constant of the defect-free perovskite nanocrystalline structure which is obtained in an X-ray diffraction (XRD) pattern, provided that a is a lattice constant representing a length along an a-axis, b is a lattice constant representing a length along a b-axis, and c is a lattice constant representing a length along a c-axis.

In one aspect, the defect-free perovskite nanocrystal may display a photoluminescence peak in a 480 to 550 nm wavelength region of a photoluminescence (PL) spectrum.

In one aspect, the defect-free perovskite nanocrystal may have an average size of 1 to 50 nm.

In one aspect, the defect-free perovskite nanoplatelet may have a thickness of 1 to 10 nm, and a lateral size of 5 to 15 nm.

In one aspect, the BF₄⁻ anion surface-modified CsPbX₃ (wherein X is a halogen) perovskite nanocrystal may be CsPbX₃ (wherein X is a halogen) perovskite nanocrystal treated with nitrosonium tetrafluoroborate (NOBF₄).

Further, another aspect of the present disclosure relates to a method of manufacturing the above described defect-free perovskite nanocrystal, wherein the method includes steps of a) preparing a CsPbX₃ (wherein X is a halogen) perovskite nanocrystal; and b) surface-treating the nanocrystal solution by adding a solution of nitrosonium tetrafluoroborate (NOBF₄).

In another aspect, the CsPbX₃ (wherein X is a halogen) perovskite nanocrystal may be prepared by steps of (i) preparing a precursor solution including PbX₂ (wherein X is a halogen), a fatty acid, and a fatty amine; and (ii) preparing a perovskite nanocrystal by mixing cesium oleate in the precursor solution.

In this case, the fatty acid may be one or more selected from a group consisting of oleic acid, palmitoleic acid, vaccenic acid, and paullinic acid, and the fatty amine may be one or more selected from a group consisting of hexylamine, octylamine, decylamine, dodecylamine, and oleylamine, and the cesium oleate may be added in an amount of 0.01 to 1 ml per 1 ml of the precursor solution.

Another aspect of the present disclosure relates to a light-emitting device including the aforementioned defect-free perovskite nanocrystal.

A defect-free perovskite nanocrystal according to the present disclosure can provide a near-defect-free perovskite nanocrystal by effectively reducing surface defects by modifying a surface of CsPbX₃ (wherein X is a halogen) perovskite nanocrystal with BF₄⁻ anions. BF₄⁻ anions can stably bind to defect sites on a nanocrystal surface, and inhibit a non-radiative recombination pathway, resulting in improved photoluminescence quantum efficiency (PLQY), and a significant increase in thermal stability. This modification can minimize a thermally activated non-radiative quenching, enabling superior performance in optoelectronic devices which require a high stability. In particular, structural and optical properties remain stable even at high temperatures, thereby improving the lifetime and efficiency of the device.

### BRIEF DESCRIPTION OF THE DRAWINGS

The above and other objectives, features, and other advantages of the present disclosure will be more clearly understood from the following detailed description taken in conjunction with the accompanying drawings, in which:

FIG. 1 shows a conceptual diagram outlining a process of NOBF₄ treatment of a CsPbBr₃ perovskite nanocrystal according to one embodiment of the present disclosure;

FIGS. 2A to 2E show a transmission electron microscopy (TEM) image of a CsPbBr₃ perovskite nanocrystal as a function of NOBF₄ treatment concentration;

FIGS. 3A to 3J show a plot of size and inter-nanocrystal distance distributions of a CsPbBr₃ perovskite nanocrystal as a function of NOBF₄ treatment;

FIGS. 4A to 4B show analysis results concerning photoluminescence (PL) and absorption spectral changes, and PL peak and full width at half maximum (FWHM) of a NOBF₄-treated CsPbBr₃ perovskite nanocrystal;

FIGS. 5A to 5B show a graph of reflectance and Raman spectra of CsPbBr₃ perovskite nanocrystal as a function of NOBF₄ treatment concentration;

FIGS. 6A to 6B show a photoluminescence quantum efficiency (PLQY) graph, and a time-resolved photoluminescence (TRPL) graph of a CsPbBr₃ nanocrystal as a function of NOBF₄ treatment;

FIGS. 7A to 7B show an average decay time analysis of a NOBF₄-treated CsPbBr₃ perovskite nanocrystal;

FIG. 8 shows an X-ray diffraction (XRD) pattern of a NOBF₄-treated CsPbBr₃ perovskite nanocrystal;

FIG. 9 shows a Fourier transform infrared spectroscopy (FTIR) spectrum of a NOBF₄-treated CsPbBr₃ perovskite nanocrystal;

FIG. 10 shows an X-ray photoelectron spectroscopy (XPS) (F 1s) spectrum of a CsPbBr₃ nanocrystal as a function of NOBF₄ treatment concentration;

FIGS. 11A to 11B show an XPS (Pb 4f) spectrum, and ¹⁹F nuclear magnetic resonance (NMR) spectrum of a NOBF₄-treated CsPbBr₃ perovskite nanocrystal;

FIG. 12 shows an XPS (F 1s) spectrum of a NOBF₄-treated CsPbBr₃ perovskite nanocrystal, and a perovskite precursor;

FIGS. 13A to 13F show an XPS (C 1s, N 1s, O 1s, Cs 3d, Pb 4f, and Br 3d) spectrum of a NOBF₄-treated CsPbBr₃ perovskite nanocrystal;

FIG. 14 shows a graph comparing a ¹⁹F NMR spectrum of a NOBF₄-treated CsPbBr₃ perovskite nanocrystal with that reported in previous literatures;

FIGS. 15A to 15B show a high-resolution TEM image of a NOBF₄-treated CsPbBr₃ perovskite nanocrystal;

FIG. 16 shows a thermogravimetric analysis (TGA) curve of a NOBF₄-treated CsPbBr₃ perovskite nanocrystal;

FIG. 17 shows a zeta potential distribution of a NOBF₄-treated CsPbBr₃ perovskite nanocrystal;

FIG. 18 shows an electron paramagnetic resonance (EPR) spectrum of a NOBF₄-treated CsPbBr₃ perovskite nanocrystal;

FIGS. 19A to 19B show a PL emission spectrum of a NOBF₄-treated CsPbBr₃ perovskite nanocrystal as a function of temperature;

FIG. 20 shows a normalized PL intensity of a NOBF₄-treated CsPbBr₃ perovskite nanocrystal as a function of temperature;

FIG. 21 shows a trap activation energy of a NOBF₄-treated CsPbBr₃ perovskite nanocrystal, calculated based on a PL intensity and a temperature dependence;

FIG. 22 shows a PL spectrum FWHM variation of a NOBF₄-treated CsPbBr₃ perovskite nanocrystal as a function of temperature;

FIG. 23 shows an exciton-longitudinal optical (LO) phonon coupling coefficient, and energy of a NOBF₄-treated CsPbBr₃ perovskite nanocrystal, calculated based on a temperature dependence of a PL FWHM;

FIG. 24 shows a PL decay spectrum as a function of emission wavelength of a NOBF₄-treated CsPbBr₃ perovskite nanocrystal, measured at 80 K;

FIG. 25 shows a TRPL graph, and analysis results of decay components of a NOBF₄-treated CsPbBr₃ perovskite nanocrystal as a function of NOBF₄ treatment concentration, measured at 80 K;

FIGS. 26A to 26D show a 2D pseudo color map of TRPL as a function of temperature change from 80 K to 300 K, respectively showing data for a pure, N1, N10, and N60 in a PL emission range 480-550 nm;

FIGS. 27A to 27D show temperature-dependent TRPL spectra of a pure nanocrystal, and NOBF₄-treated CsPbBr₃ perovskite nanocrystals (N1, N10, N60);

FIGS. 28A to 28D respectively show a temperature-dependent T1 lifetime, T2 lifetime, ratio of each lifetime component, and average PL lifetime data of pure nanocrystal (NO), and NOBF₄-treated CsPbBr₃ perovskite nanocrystals (N1, N10, N60);

FIG. 29 shows a variation of a high-energy shoulder peak and a low-energy tail of a PL emission spectrum as a function of NOBF₄ treatment concentration of CsPbBr₃ perovskite nanocrystal, measured at 80 K;

FIG. 30 shows a result showing a suppression effect of a NOBF₄-treated CsPbBr₃ perovskite nanocrystal, on a thermally active trap;

FIGS. 31A to 31D show a Tauc plot of a pure nanocrystal, and NOBF₄-treated CsPbBr₃ perovskite nanocrystals (N1, N10, N60);

FIGS. 32A to 32D show a near-Eg absorption coefficient (a) spectra of a pure nanocrystal, and NOBF₄-treated CsPbBr₃ perovskite nanocrystals (N1, N10, N60);

FIGS. 33A to 33D show SEM images, and FIGS. 33E to 33H show AFM topography images (5×5 μm², versus height), wherein a top panel is a 2D images, a bottom panel is their corresponding 3D images, wherein FIGS. 33A and 33E are a pure nanocrystal, FIGS. 33B and 33F are a N1 nanocrystal, FIGS. 33C and 33G are a N10 nanocrystal, and FIGS. 33D and 33H are a N60 nanocrystal;

FIGS. 34A to 34D show data consisting of optical microscopy images, PL (a luminescence intensity and a wavelength) mapping images, and PL spectra, for pure, N10, N30, and N60 nanocrystals, wherein the PL spectra (red, orange, and green) were measured at positions indicated by colored arrows in PL mapping images;

FIGS. 35A to 35D show data consisting of TRPL mapping images (left panel), and TRPL spectra (right panel) for pure, N10, N30, and N60 nanocrystals. TRPL spectra (red, orange, green) were measured at positions indicated by colored arrows in the TRPL mapping images;

FIGS. 36A to 36D show 2D PLE mapping images of a pure nanocrystal, and NOBF₄-treated CsPbBr₃ perovskite nanocrystals (N1, N10, N60) displaying a PL intensity as a function of excitation wavelength on a color scale;

FIGS. 37A to 37F show PL mapping images and PL spectra of CsPbBr₃ perovskite nanocrystal (N0.2-OA) co-treated with different amount of oleic acid (OA) and NOBF₄, wherein the PL spectra (red, orange, green) were measured at positions indicated by colored arrows in PL mapping images;

FIGS. 38A to 38F show TRPL mapping images and TRPL spectra of a CsPbBr₃ perovskite nanocrystal (N0.2-OA) co-treated with different amounts of OA and NOBF₄, wherein the TRPL spectra (red, orange, green) were measured at positions indicated by colored arrows in the TRPL mapping images;

FIG. 39 shows an energy band diagram of LEDs made from a NOBF₄-treated CsPbBr₃ perovskite nanocrystal;

FIG. 40 shows a luminance-current-voltage characteristic graph of LEDs made from a NOBF₄-treated CsPbBr₃ perovskite nanocrystal;

FIG. 41 shows a voltage-dependent electroluminescence (EL) spectrum of LEDs made from a NOBF₄-treated CsPbBr₃ perovskite nanocrystal;

FIG. 42 shows an International Commission on Illumination (CIE) chromaticity coordinates of LEDs made from a NOBF₄-treated CsPbBr₃ perovskite nanocrystal, and an image of the LEDs under power;

FIG. 43 shows a graph of an external quantum efficiency (EQE) of LEDs made from a NOBF₄-treated CsPbBr₃ perovskite nanocrystal whose concentration of NOBF₄ is different; and

FIG. 44 shows a histogram of an EQE of LEDs made from a NOBF₄-treated CsPbBr₃ perovskite nanocrystal.

### DESCRIPTION OF THE PREFERRED EMBODIMENTS

The following describes in detail a defect-free perovskite nanocrystal according to the present disclosure, a method of manufacturing the same, and a light-emitting device including the same. The following drawings are provided by way of example so that spirit of the present disclosure may be sufficiently conveyed to those skilled in the art. Accordingly, the disclosure may be embodied in other forms without being limited to the drawings shown herein, and the drawings shown herein may be exaggerated to clarify spirits of the present disclosure. Technical and scientific terms used herein, unless otherwise defined, have the meanings commonly understood by one of ordinary skill in the art to which this disclosure belongs, and the following description and accompanying drawings omit descriptions of known features and configurations that would unnecessarily obscure the essence of the disclosure.

One aspect of the present disclosure relates to a defect-free perovskite nanocrystal, including a CsPbX₃ (wherein X is a halogen) perovskite nanocrystal whose surface is modified with BF₄⁻ anions.

As such, a defect-free perovskite nanocrystal according to the present disclosure can effectively reduce surface defects by modifying the surface of a CsPbX₃ (wherein X is a halogen) perovskite nanocrystal with BF₄⁻ anions to provide a near-defect-free perovskite nanocrystal. BF₄⁻ anions can stably bind to defect sites on a nanocrystal surface, and inhibit a non-radiative recombination pathway, resulting in improved photoluminescence quantum efficiency (PLQY) and a significant increase in a thermal stability. This modification can minimize a thermally activated non-radiative quenching, enabling superior performance in optoelectronic devices requiring a high stability. In particular, structural and optical properties remain stable even at high temperatures, which can have an effect of improving the lifetime and efficiency of a device.

More preferably, the defect-free perovskite nanocrystal may be characterized by having a space group Pbnm which is found in the X-ray diffraction (XRD) pattern, and satisfying following equations 1 to 3:

$$8.1 \leq a \leq 8.3 Å \qquad [ Equation 1 ]$$

$$8.15 \leq b \leq 8.35 Å \qquad [ Equation 2 ]$$

$$11.6 \leq c \leq 11.9 Å , \qquad [ Equation 3 ]$$

wherein in the Equations 1 through 3,
a, b, and c each represent a lattice constant of the defect-free perovskite nanocrystalline structure which is obtained in an X-ray diffraction (XRD) pattern, provided that a is a lattice constant representing a length along an a-axis, b is a lattice constant representing a length along a b-axis, and c is a lattice constant representing a length along a c-axis.

This can provide a defect-free perovskite nanocrystal that are more stable, and have high efficiency luminescence.

In the CsPbX₃ perovskite nanocrystal, X may be a halogen, for example, F, Br, Cl or I, and preferably Br.

The BF₄⁻ anion is intended to be bound to a surface of the CsPbX₃ perovskite nanocrystal to make a crystal structure of the nanocrystal more regular and defect-free, thereby achieving improved luminescence properties. For example, a CsPbX₃ (wherein X is a halogen) perovskite nanocrystal can be treated with nitrosonium tetrafluoroborate (NOBF₄) to prepare a CsPbX₃ (wherein X is a halogen) perovskite nanocrystal whose surface is modified with BF₄⁻ anions.

As a more particular example, the defect-free perovskite nanocrystal may display a photoluminescence peak in a 480 to 550 nm wavelength region of a photoluminescence (PL) spectrum, more preferably display a photoluminescence peak in a 485 nm or more, 490 nm or more, 495 nm or more, 500 nm or more wavelength region of the photoluminescence spectrum, and may display a photoluminescence peak in a 545 nm or less, 540 nm or less, 535 nm or less, 530 nm or less, 525 nm or less, 520 nm or less wavelength region of the photoluminescence spectrum.

Meanwhile, the defect-free perovskite nanocrystal may have an average size of from 1 to 50 nm, more specifically from 2 to 30 nm, and more specifically from 5 to 20 nm.

In addition, another aspect of the present disclosure relates to a method of manufacturing the above-described defect-free perovskite nanocrystal, the method including steps of a) preparing a CsPbX₃ (wherein X is a halogen) perovskite nanocrystal; and b) surface-treating the nanocrystal solution by adding a solution of nitrosonium tetrafluoroborate (NOBF₄).

First, a step of a) preparing a CsPbX₃ (wherein X is a halogen) perovskite nanocrystal may be performed, wherein the perovskite nanocrystal may be synthesized via a modified hot injection method.

In a more specific example, the perovskite nanocrystal may be prepared by a method including steps of (i) preparing a precursor solution including PbX₂, a fatty acid, and a fatty amine; and (ii) mixing cesium oleate in the precursor solution to prepare a perovskite nanocrystal.

In one example of the present disclosure, the PbX₂ is a precursor of CsPbX₃, may be one or more selected from a group consisting of, for example, PbF₂, PbBr₂, PbCl₂, and PbI₂, and may preferably be PbBr₂.

The fatty acid may be one or more selected from a group consisting of a saturated fatty acid having 14 to 24 carbons, and an unsaturated fatty acid having 14 to 24 carbons, and more specifically one or more selected from a group consisting of, for example, oleic acid, palmitoleic acid, vaccenic acid, and paullinic acid. Such fatty acid may be added in an amount of 0.01 to 10 ml per 1 mol of PbX₂, more preferably 0.1 to 5 ml per 1 mol of PbX₂, and even more preferably 0.5 to 5 ml per 1 mol of PbX₂.

The fatty amine may be one or more selected from a group consisting of a saturated fatty amine having 14 to 24 carbons, and an unsaturated fatty amine having 14 to 24 carbons, and more particularly one or more selected from a group consisting of, for example, hexylamine, octylamine, decylamine, dodecylamine, and oleylamine. Such a fatty amine may be added in an amount of 0.01 to 10 ml per 1 mmol of PbX₂, preferably 0.1 to 5 ml per 1 mmol of PbX₂, and more preferably 0.5 to 5 ml per 1 mmol of PbX₂.

A solvent may further be used in preparing the precursor solution, and the solvent may be used without limitation as long as it is non-reactive, for example, toluene or the like. The solvent may be added in an amount of 10 to 200 ml per 1 mmol of PbX₂, preferably in an amount of 15 to 150 ml per 1 mmol of PbX₂, more preferably in an amount of 50 to 150 ml per 1 mmol of PbX₂.

When the precursor solution is prepared, the solution can be mixed and react with a cesium oleate, wherein a reaction temperature can be from 100 to 200° C. The cesium oleate can be prepared by dissolving a cesium carbonate (Cs₂CO₃) in oleic acid, wherein 0.01 to 1 ml of a cesium oleate may be mixed and react with 1 ml of the precursor solution, preferably 0.05 to 0.5 ml of cesium oleate may be mixed and react with 1 ml of the precursor solution.

Next, a step of b) adding a solution of nitrosonium tetrafluoroborate (NOBF₄) to the nanocrystal solution for surface treatment may be performed.

A concentration of the nanocrystal solution may be from 1 to 50 mg/mL, and preferably from 5 to 30 mg/mL, but is not necessarily limited thereto.

As for the nitrosonium tetrafluoroborate (NOBF₄) solution, it may be prepared by dissolving a nitrosonium tetrafluoroborate (NOBF₄) in an acetone, but not be limited this method, wherein a concentration of the solution may be from 0.1 to 20 mg/mL, and preferably from 1 to 10 mg/mL.

Meanwhile, another aspect of the present disclosure relates to a light-emitting device including the aforementioned defect-free perovskite nanocrystal, wherein the light-emitting device may be a display, an illumination, a laser, or a fiber optic communication irradiation device, and the like, but is not necessarily limited thereto.

Hereinafter, a defect-free perovskite nanocrystal according to the present disclosure, a method of manufacturing the same, and a light-emitting device including the same will be described in more detail by way of examples. However, the following examples are merely a reference for describing the present disclosure in detail, but are not intended to limit the disclosure, which may be embodied in various forms.

Further, unless otherwise defined, all technical and scientific terms have the same meanings as commonly understood by one of ordinary skill in the art to which the disclosure belongs. The terms used in the description herein are intended only to effectively describe certain embodiments, and are not intended to limit the disclosure. Moreover, the units of additives not specifically stated in the specification may be wt %.

### Characterization Methods

High resolution transmission electron microscopy (TEM) images were obtained using a JEM-2100 (JEOL Ltd.) operating at 200 kV. X-ray diffraction (XRD) patterns of CsPbBr₃ NC were collected with a Bruker D8 ADVANCE diffractometer using Cu-Koa radiation (λ=1.54 Å). A surface morphology, and a roughness of a NC film were characterized using an atomic force microscopy (AFM, Asylum Research MFP-3D-BIO, Oxford Instruments), and a scanning electron microscopy (SEM, Hitachi S-4800). Raman spectra were obtained using a UniRAM UR1207J spectrometer (UniThink Inc.). X-ray photoelectron spectroscopy (XPS) spectra of NC were obtained using a Thermofisher Scientific K-Alpha+ apparatus with a monochromated X-ray source of Al Kα (hv=1486.6 eV). Ultraviolet photoelectron spectroscopy (UPS) spectra of NCs were acquired using a Thermofisher Scientific Nexsa G2 with He I radiation (hv=21.22 eV). Thermogravimetric analysis (TGA) curves were obtained up to 800° C. (10° C./min) in a N₂ atmosphere using a Mettler-ToLEDso TGA/DSC1 apparatus. Fourier transform infrared spectroscopy (FTIR) spectra (4000-400 cm⁻¹) of NCs were obtained using a Bruker VERTEX 80v spectrometer. Zeta potential of the NC solutions was measured using a Zetasizer Nano ZS (Malvern Instruments). Electron paramagnetic resonance (EPR) measurements were performed using a JES-FA100 (JEOL) system at room temperature in the dark, and EPR spectra were obtained under cryogenic conditions (T=5 K) with a frequency of 9.65 GHz in a X band, a power of 1 mW, a modulation amplitude of 10 G, a modulation frequency of 100 kHz, and a receiver time constant of 40.96 ms. ¹H liquid-phase nuclear magnetic resonance (NMR) experiments were performed on a Bruker AVANCE III 600 (600 MHz). ¹⁹F magic angle spinning (MAS) solid-state NMR measurements were performed using a Varian VNMRS 600 solid-state system (564.59 MHz, rotation speed 20 kHz, 30 degrees) with a 3.2 mm probe. Inductively coupled plasma-atomic emission spectroscopy (ICP-AES) was performed on a Perkin-Elmer OPTIMA 7300 DV, and inductively coupled plasma-mass spectrometry (ICP-MS) spectra were acquired on a Perkin-Elmer ELAN DRC II.

A UV-vis absorption spectrum and a photoluminescence (PL) spectrum were measured under atmospheric conditions using a Shimadzu UV-2600 UV-vis and an Edinburgh FS5 fluorescence spectrometer (Edinburgh Instruments, UK), respectively. Cryogenic PL spectroscopy measurements were performed in a temperature range of 80 to 300 K using an FS5 spectrofluorometer and an SC-80 cryostat module. Time-resolved PL (TRPL) decay spectra were also obtained using an Edinburgh FS5 with a time-correlated single photon counting (TCSPC) with a 370.4 nm laser excitation source. Fluorescence decay curves were fitted with a double exponential function fit:

$$I ( t ) = C + {α}_{1} exp ( - \frac{t}{{τ}_{1}} ) + {α}_{1} exp ( - \frac{t}{{τ}_{1}} ) , \qquad ( 1 )$$

wherein I(t) is a PL intensity, I is a lifetime, α is an all-exponential coefficient, and C is a constant. The average lifetime (τ_{avg}) was calculated as an average of a double exponential decay:

$${τ}_{avg} = \frac{{α}_{1} {τ}_{1}^{2} + {α}_{2} {τ}_{2}^{2}}{{α}_{1} {τ}_{1} + {α}_{2} {τ}_{2}} = {f}_{1} {τ}_{1} + {f}_{2} {τ}_{2} + A , \qquad ( 2 )$$

wherein f is a contribution of each decay component, and A is a constant. An accuracy of a fitting was evaluated by a χ² value, which was found to be within a range of 1±0.2.

### Preparative Example 1. Synthesis and NOBF₄ Treatment of CsPbBr₃ Nanocrystals

1-Octadecene (ODE, 40 mL) and oleic acid (OA, 2.5 mL) were placed in a 100 mL two-necked round-bottom flask equipped with a magnetic stirrer. The flask was heated to 120° C., and maintained under a stream of N₂ for 1 hour. Cesium carbonate (Cs₂CO₃, 0.814 g) was added to the flask, and the mixture was stirred at 150° C. until the Cs₂CO₃ completely reacted with the OA under a stream of N₂. A prepared Cs oleate was stored for further use.

Subsequently, a CsPbBr₃ nanocrystal was synthesized according to a modified hot injection method. PbBr₂ (0.276 g), ODE (20 mL), OA (2 mL), and oleylamine (OlAm, 2 mL) were placed in a 50 mL flask, and dried at 120° C. under vacuum for 1 hr. The temperature was then raised to 160° C. under a stream of N₂. Cs oleate (1.6 mL) was preheated to 130° C., and was quickly added to a reaction mixture under strong stirring. A reaction was terminated after 5 s by immersing the flask in ice water. For purification, ethyl acetate (60 mL) was added to the crude solution. The mixture was stirred or sonicated for 2 min, then centrifuged at 8000 rpm for 5 min to remove unreacted reagents. A supernatant was discarded, and a precipitate was collected and dispersed in hexanes (12 mL). Ethyl acetate (36 mL) was added for a second wash. The mixture was stirred or sonicated for 1 minute, and then centrifuged at 8000 rpm for 2 minutes. Precipitates were collected, and finally dispersed in octane (2.4 mL). The dispersion was further centrifuged at 4000 rpm for 5 minutes to remove aggregates. A concentration of a final colloidal solution was determined by weighing a solid residue after drying at 100° C. For LED fabrication, the concentration of the CsPbBr₃ nanocrystal solution was adjusted to 20 mg/mL.

Next, the NOBF₄ solution was prepared by dissolving the NOBF₄ salt in an acetone at a concentration of 5 mg/mL. The prepared NOBF₄ solution turns brown after a few hours, wherein all solutions were used in a fresh condition because strong and unpredictable reactions are observed in a brown NOBF₄ solution. For a surface modification of a CsPbBr₃ nanocrystal, a certain amount of NOBF₄ solution was added to an ethyl acetate used in a second washing step. For example, 0.03 to 27 mL of a NOBF₄ solution was added instead of ethyl acetate. It should be noted that using excessive amount of a NOBF₄ solution (13.5 mL) may result in white precipitates.

### Preparative Example 2. Fabrication of NOBF₄-Treated CsPbBr₃ Nanocrystal LEDs

A patterned ITO glass substrate (25 mm×25 mm) was ultrasonically washed in deionized water, acetone, and isopropyl alcohol each for 15 minutes. The substrate was washed for an additional 15 minutes by a N₂ blowing and an UV-ozone treatment. A poly(3,4-ethylenedioxythiophene):polystyrene sulfonate (PEDOT:PSS) solution (Clevios P VP Al4083) was filtered through a 0.45 μm polyethersulfone (PES) filter, and spin-coated onto the substrate at 8000 rpm for 15 seconds. The substrate was heat treated at 150° C. for 15 minutes, and then transferred to a nitrogen-filled glove box (H₂O<1 ppm, O₂<1 ppm). As a hole transport layer, poly-TPD (1 mg/ml in benzene chloride) and formamidinium bromide (7.5 mg/ml in dimethylformamide) were deposited by a spin coating at 4000 rpm for 60 s each. The CsPbBr₃ nanocrystal solution was spin coated for 15 s at 2000 rpm. The prepared substrate was then transferred to a thermal evaporator. TPBi (55 nm), LiF (2 nm), and Al (80 nm) layers were deposited sequentially at deposition rates of 0.35, 0.1, and 2.0 Å/s under high vacuum conditions (<2.0×10⁻⁵ torr), respectively. Finally, LED devices were encapsulated with UV-cured epoxy (NOA71) in a glove box. An active area of the device (4 mm²) was defined as an overlapping area of ITO and Al electrodes.

### Results and Discussion

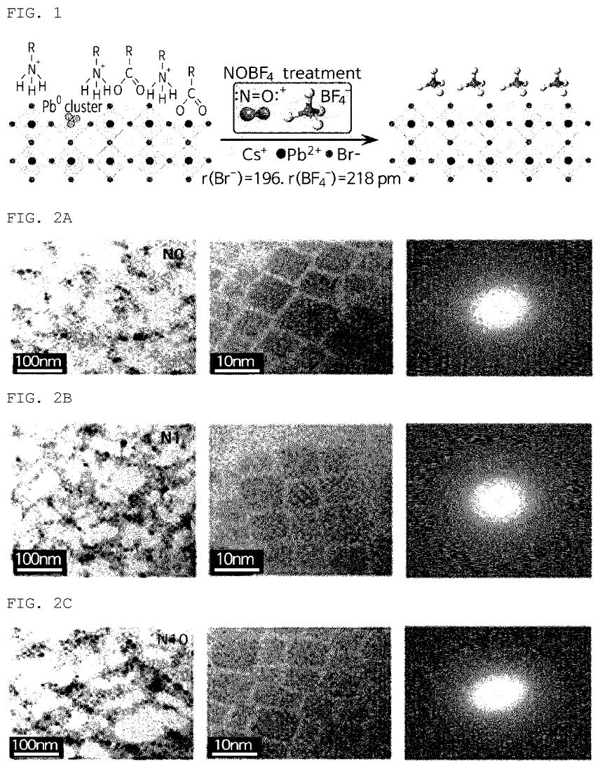

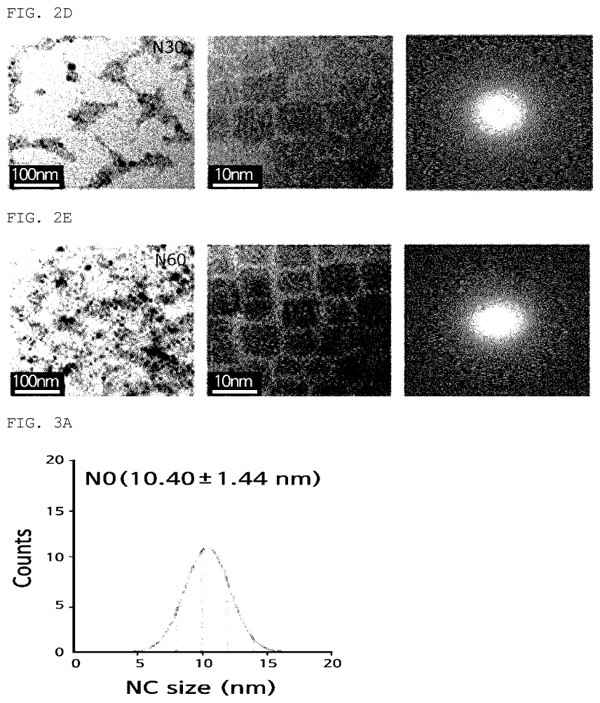

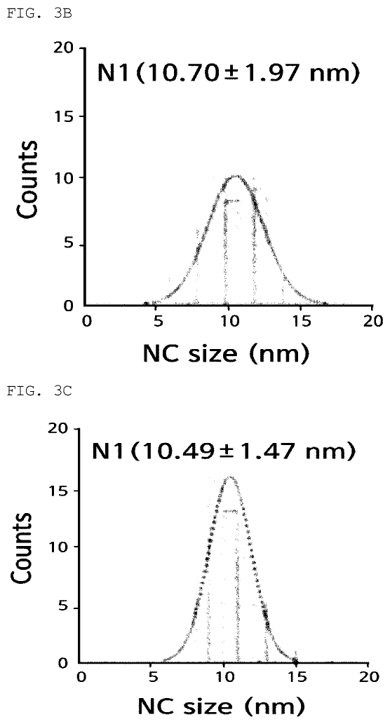

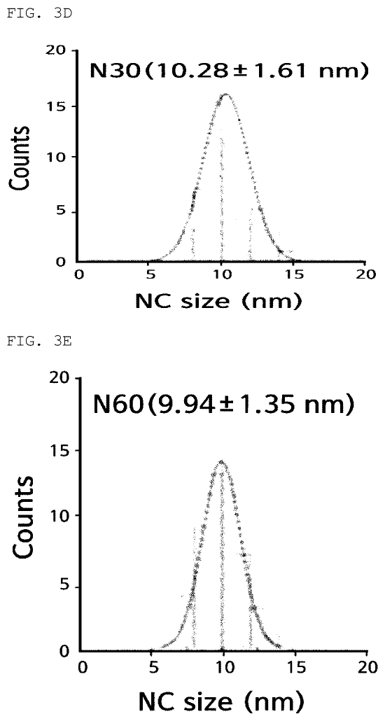

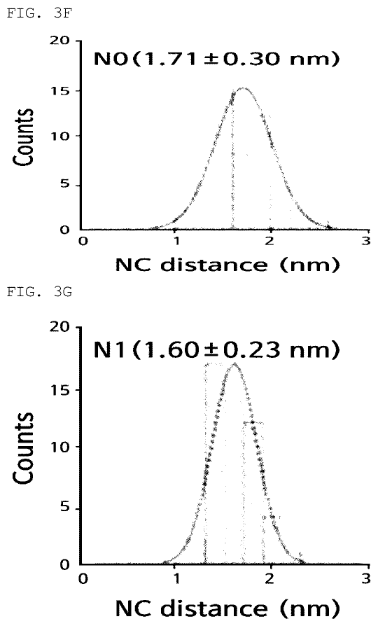

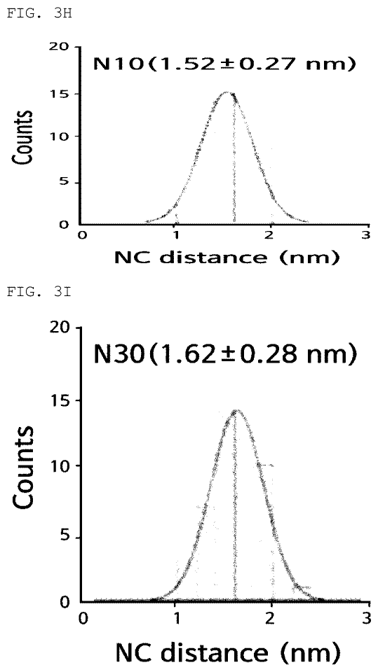

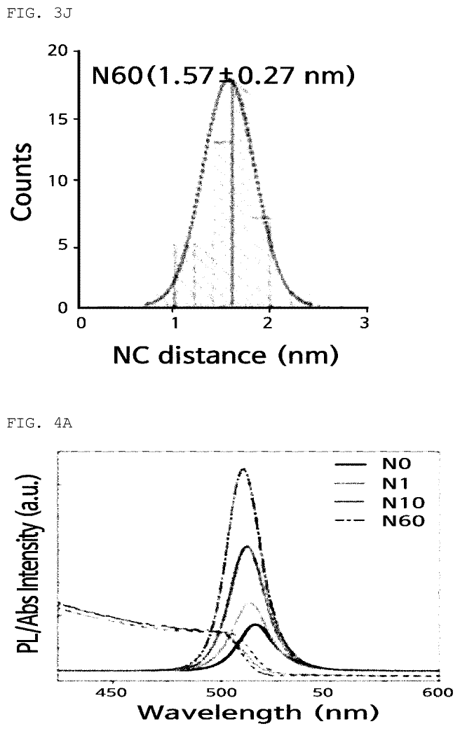

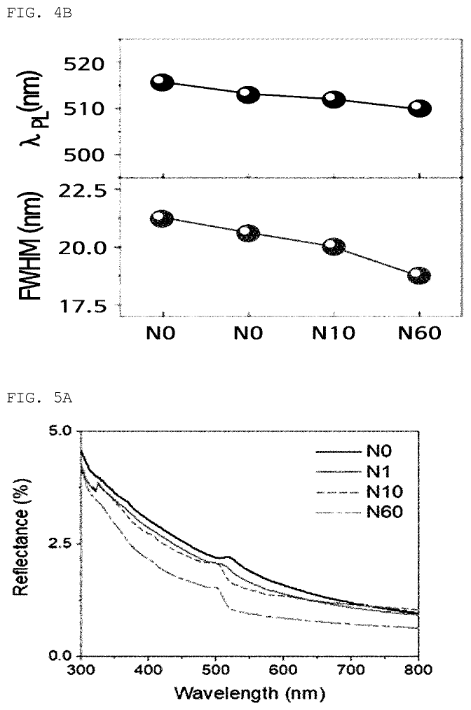

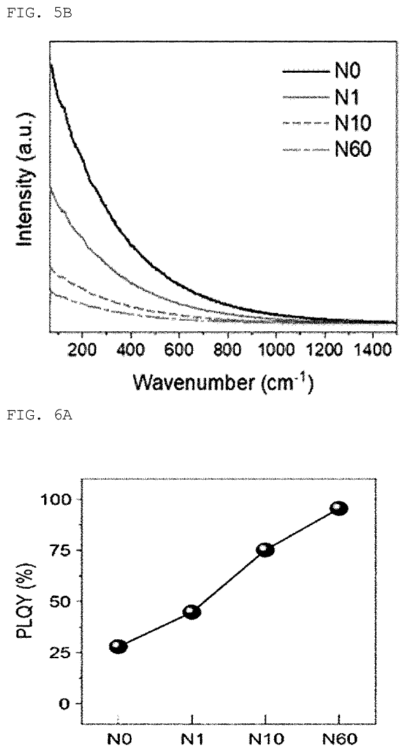

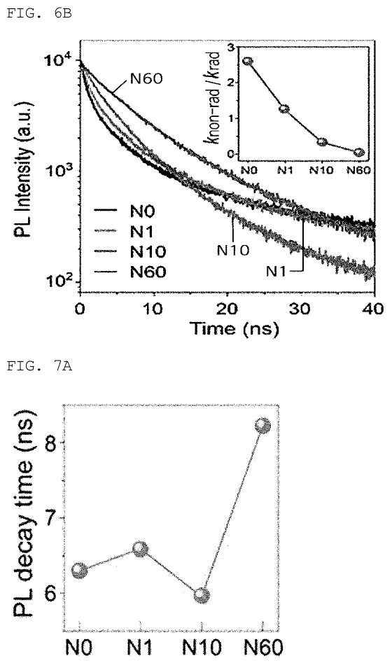

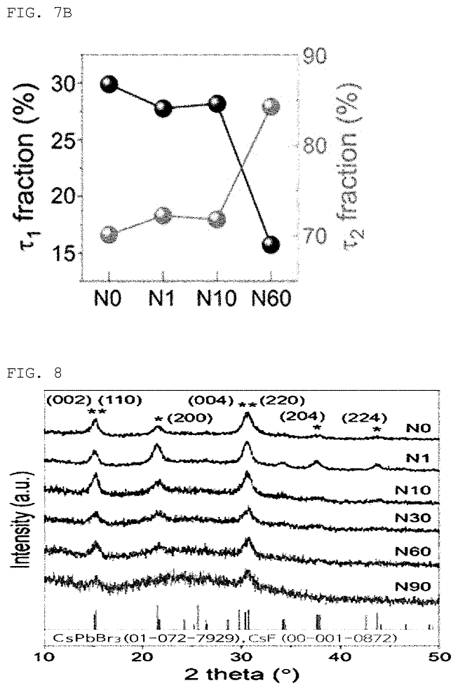

An oxidizing ability, and Lewis acidic nature of NO⁺ cations suggest that a NOBF₄ post-treatment on a CsPbBr₃ nanocrystal can efficiently remove an intrinsic organic ligand such as oleic acid (OA), and an oleylamine (OlAm), while maintaining reduced surface defects on a CsPbBr₃ nanocrystal surface by weakly bound BF₄⁻ anions (FIG. 1). In the present disclosure, a molar ratio of CsPbBr₃ nanocrystal to NOBF₄ was adjusted in a range of 1:0 to 1:11, and representative samples were named as (i) NO (1:0), (ii) N1 (1:0.124), (iii) N10 (1:1.24), and (iv) N60 (1:7.45). Transmission electron microscopy (TEM) images showed pristine nanocrystal, and NOBF₄-treated CsPbBr₃ nanocrystals as a function of NOBF₄ concentration (N0-N60) (FIGS. 2A to 2E). Although an overall square shape of the nanocrystals was maintained, the size decreased slightly from 10.40±1.44 nm to 9.94±1.35 nm, suggesting that there was a slight etching effect on the CsPbBr₃ nanocrystals during an original ligand removal process (FIGS. 3A to 3J). Interestingly, a PL luminescence continuously increased with the NOBF₄ concentration, and a PL peak and an absorption wavelength of NOBF₄-treated CsPbBr₃ nanocrystal showed a slight blue shift (~5.6 nm) from 515.6 nm to 510 nm (FIGS. 4A to 4B), while PL luminescence spectra were narrower with a minimum FWHM of 18.6 nm (N60 sample). These results show that further crystal growth or layer separation of a CsPbBr₃ nanocrystal was not caused by additional NOBF₄ treatments (FIGS. 5A to 5B). Furthermore, in case of the NOBF₄-treated CsPbBr₃ nanocrystal (N60), almost 100% PLQY was observed with an increase in an average decay time from 6.30 ns to 8.23 ns (FIGS. 6 and 7). Differences in carrier kinetics can be estimated by calculating radioactive recombination rate (krad) and non-radioactive recombination rate (knon-rad) (Tables 1 and 2).

TABLE 1

| | τ_{avg} (ns) | τ₁ (ns) | f₁ (%) | τ₂ (ns) | f₂ (%) |
|---|---|---|---|---|---|
| N0 | 6.30 | 1.08 | 29.88 | 8.52 | 70.12 |
| N1 | 6.59 | 1.34 | 27.76 | 8.61 | 72.24 |
| N10 | 5.96 | 2.16 | 28.18 | 7.45 | 71.82 |
| N60 | 8.23 | 2.84 | 15.72 | 9.23 | 84.28 |

TABLE 2

| | | | | knon-rad | knon- |
|---|---|---|---|---|---|
| | PLQY (%) | τ_{avg} (ns) | krad (MHz) | (MHz) | rad/krad |
| N0 | 27.79 | 6.30 | 44.10 | 114.60 | 2.60 |
| N1 | 44.66 | 6.59 | 67.75 | 83.95 | 1.24 |
| N10 | 75.10 | 5.96 | 126.08 | 41.80 | 0.33 |
| N60 | 95.44 | 8.23 | 116.02 | 5.54 | 0.05 |

An inset graph in FIGS. 6A to 6B show that a PLQY enhancement of the CsPbBr₃ nanocrystals by NOBF₄ treatment is attributed to a decrease in the non-radiative recombination rate (knon-rad). Thus, the results of this study show that NOBF₄ treatment significantly enhances the radiative recombination of photoexcited charge carriers within the CsPbBr₃ nanocrystals, maintaining a structural integrity of the nanocrystal surface. This implies that a chemical reaction involving NOBF₄ molecules at the nanocrystal surface and an interface efficiently inhibits an exciton transfer to a non-radiative recombination pathway.

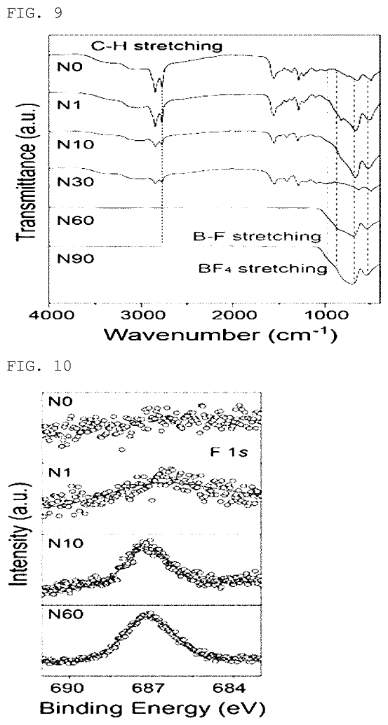

To understand a role of NOBF₄ treatment on a structure and surface properties of CsPbBr₃ nanocrystal, X-ray diffraction (XRD) patterns and Fourier transform infrared (FTIR) spectra were measured. All nanocrystals exhibited a clearly defined tetragonal CsPbBr₃ phase (PDF #01-072-7929), and space group Pbnm (a=8.207, b=8.255, c=11.759 Å) (FIG. 8). Peak shifts or additional peaks, which indicates by-products such as CsF and PbF₂ that could be generated by NOBF₄ treatment, were not observed. However, an FTIR spectrum showed that when NOBF₄ concentration increases, C—H signals at 2853 and 2922 cm⁻¹ decreased significantly, while B—F and BF₄ signals at 764, 904, and 1057 cm⁻¹ increased (FIG. 9). Notably, the C—H signals completely disappeared, leaving only the B—F and BF₄ signals in N60 and N90 samples. The TEM images and corresponding energy dispersive X-ray (EDX) analysis also confirmed a presence of BF₄ molecules on a surface of CsPbBr₃ nanocrystal. These results suggest that intrinsic organic ligands such as OA and OlAm, were effectively exchanged with BF₄⁻ anions on the CsPbBr₃ nanocrystal surface after NOBF₄ treatment.

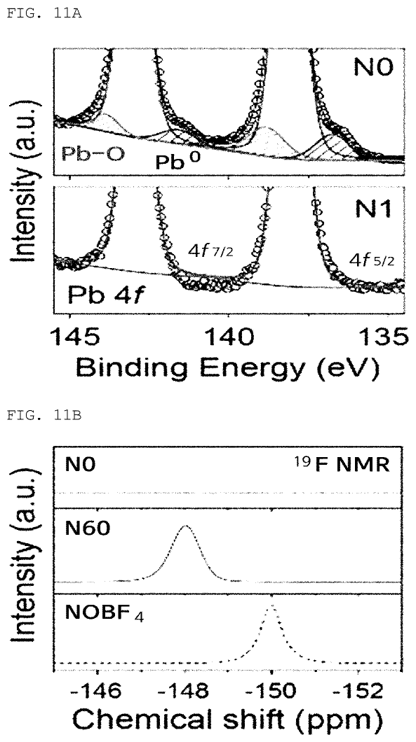

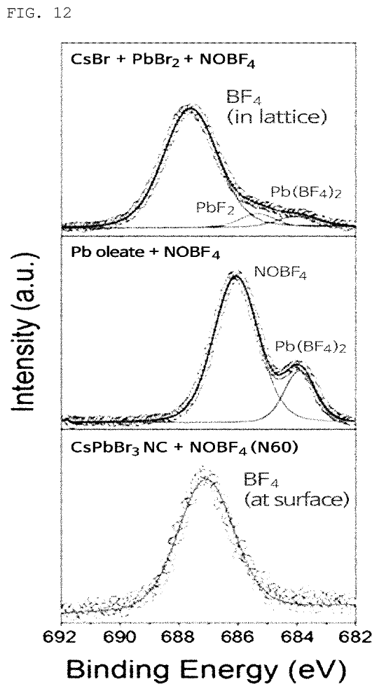

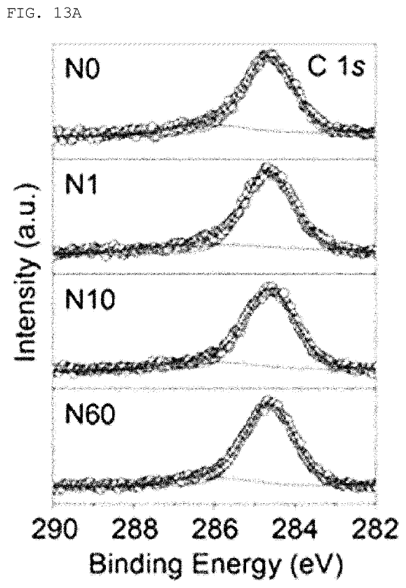

A chemical bonding property of a NOBF₄-treated CsPbBr₃ nanocrystal was further investigated by X-ray photoelectron spectroscopy (XPS), which provided deeper insight into chemical states associated with an interaction of NOBF₄ molecules with surfaces containing Br⁻ defects, Cs⁺ and Pb²⁺ ions, and [PbBr₆]⁴⁻ octahedra in the CsPbBr₃ nanocrystal (FIGS. 10 and 11). The high-resolution F 1s spectrum of the NOBF₄-treated CsPbBr₃ nanocrystal clearly showed a single peak at 687.1 eV corresponding to —BF₄⁻, which became more pronounced with increasing NOBF₄ concentration (from N1 to N60) (FIG. 10). Further chemical bonds of a CsPbBr₃ nanocrystal precursor (i.e., CsBr and PbBr₂), and Pb oleic acid with BF₄⁻ anions were investigated via a formation pathway of unwanted by-products such as CsF and PbF₂ (FIG. 12). In particular, an additional F 1s peak corresponding to Pb(BF₄)₂ (~683.9 eV) was observed for a CsPbBr₃ precursor, and a Pb oleic acid, suggesting that a reaction pathway between the BF₄⁻ anions and a Pb(II) metal complex is present. However, such additional peaks were not observed in a NOBF₄-treated CsPbBr₃ nanocrystal, suggesting that the BF₄⁻ anions are well coordinated on a CsPbBr₃ nanocrystal surface. Notably, a binding energy of F 1s peak was observed to be higher (~0.5 eV) when polycrystalline CsPbBr₃ films were produced containing BF₄⁻ anions, suggesting that BF₄⁻ anions were incorporated within a CsPbBr₃ crystal lattice. Thus, it can be confirmed that BF₄⁻ anions were effectively bound to the CsPbBr₃ nanocrystal surface by NOBF₄ treatment.

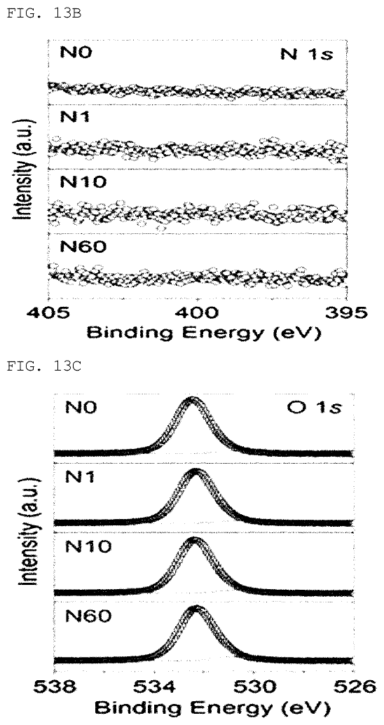

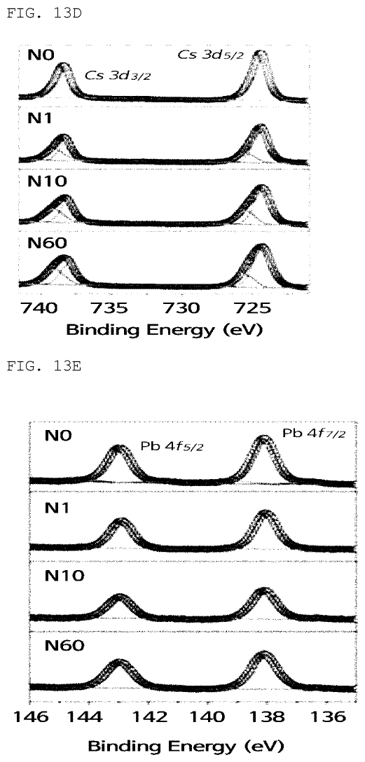

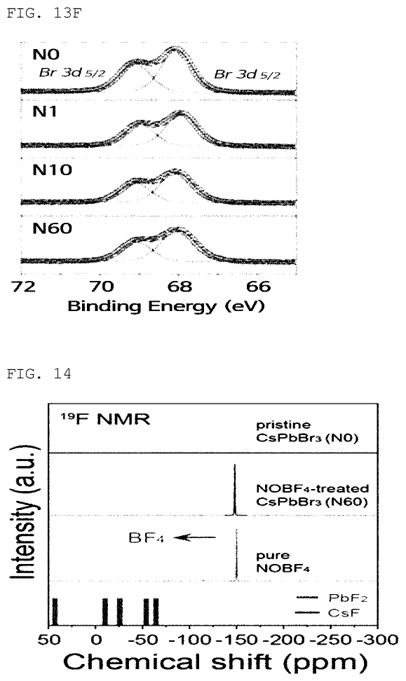

Furthermore, in Cs 3d spectra of the NOBF₄-treated CsPbBr₃ nanocrystals, well-separated additional peaks for Cs 3d_{3/2} (738.3 and 739.5 eV) and Cs 3d_{5/2}(724.0 and 725.8 eV) were observed, while only single peaks (Cs 3d3/2 at 738.3 eV, Cs 3d5/2 at 724.0 eV) were seen in an original CsPbBr₃ nanocrystal (FIGS. 13A to 13F). In Cs oleic acid and NOBF₄ mixture, additional peaks were not observed in F 1s and Cs 3d spectra. Therefore, it can be inferred that BF₄⁻ anions form strong bonds with Cs⁺ ions on a surface of the CsPbBr₃ nanocrystal, resulting in an appearance of additional chemical states at higher binding energies. Furthermore, Pb 4f XPS spectra showed that due to a strong oxidizing nature of NO⁺, only an addition of a small amount of NOBF₄ (N1) completely eliminated metallic Pb⁰ and Pb—O states that cause exciton capture (FIGS. 11A to 11B). These results suggest that a NOBF₄ treatment is effective in reducing intrinsic surface defects created during synthesis and subsequent washing, and preventing further defect formation through ligand dynamics in a liquid phase.

A solid-state ¹⁹F NMR spectra strongly supported a presence of BF₄⁻ bonds on a surface of the NOBF₄-treated CsPbBr₃ nanocrystal, which exhibited a distinct single signal (−148 ppm) corresponding to a BF₄⁻ molecule bound to a surface (FIGS. 11A to 11B). A chemical shift of this peak, compared to that of NOBF₄ powder (−150 ppm), suggests that the BF₄⁻ molecule interacts with the nanocrystal surface to induce an electron-deficient environment around a ¹⁹F nucleus of BF₄⁻. A slight broadening of a signal due to an interaction between a ligand and a nanocrystal surface is also consistent with that of literatures. On the other hand, typical ¹⁹F NMR signals of PbF₂ and CsF were not observed in a NOBF₄-treated CsPbBr₃ nanocrystal, confirming an absence of unwanted by-products (FIG. 14). A presence of boron was further confirmed by inductively coupled plasma-atomic emission spectroscopy (ICP-AES) (Table 3).

TABLE 3

| | B (ppm) | Pb (ppm) | Cs (ppm) |
|---|---|---|---|
| N0 | Out of range | 4386 | 44667.857 |
| | (<10) | | |
| N10 | 105 | 7290 | 45204.075 |

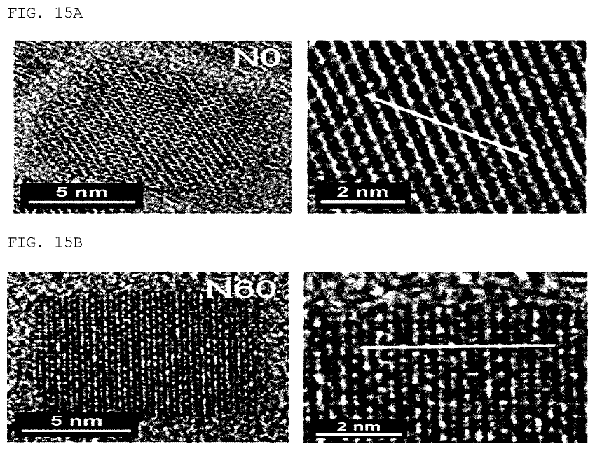

Next, a lattice distortion that may occur when BF₄⁻ anions are incorporated into a lattice of CsPbBr₃ nanocrystal was investigated. The lattice distortion may still occur because ionic radii of the BF₄⁻ anions are well suited to halide positions in the perovskite lattice (BF₄⁻=218 μm, I⁻=220 μm, Br⁻=196 pm, FIGS. 15A to 15B). However, all NOBF₄-treated CsPbBr₃ nanocrystals exhibited the same lattice spacing (0.581±0.002 nm), confirming an absence of anion exchange within a CsPbBr₃ perovskite lattice. Furthermore, a possibility of anion exchange between Br⁻ and BF₄⁻ can be dismissed in view of an absence of clear changes in Pb 4f and Br 3d XPS spectra.

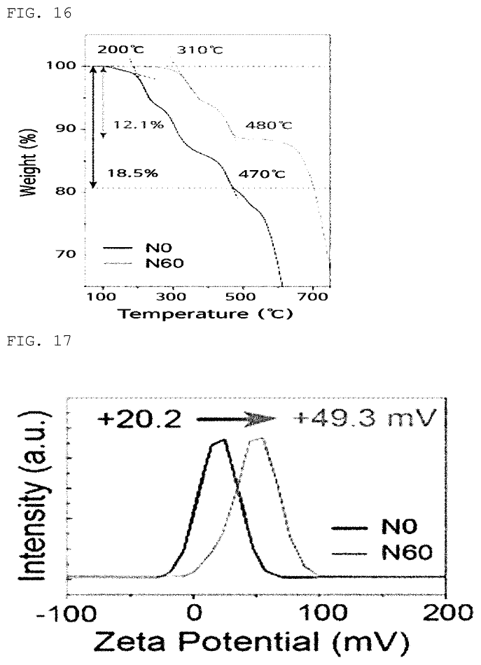

A thermogravimetric analysis (TGA) thermal decomposition curves confirmed that a NOBF₄ treatment was effective in removing a significant portion of bound ligands (OA and OlAm) from a surface of CsPbBr₃ nanocrystal, which showed a 34.6% reduction compared to pristine CsPbBr₃ nanocrystal (FIG. 16). In addition, the NOBF₄-treated CsPbBr₃ nanocrystal exhibited much improved thermal stability at temperatures above 480° C. This indicates that BF₄⁻ anions strongly bound to a surface of CsPbBr₃ nanocrystal inhibited a thermal decomposition of ionic components, thus hindering structural and compositional modifications of the nanocrystal. Based on these observations, it is suggested that long hydrocarbon molecules containing coordination head groups such as OA and OlAm, could be easily removed through a substitution of CsBr or PbBr₂ ion pairs in a presence of NOBF₄. In addition, BF₄⁻ anions easily bonded with positively charged CsPbBr₃ surface metal centers, which promoted a thermal and electrostatic stabilization of colloidal dispersions.

A zeta potential distribution of a colloidal CsPbBr₃ nanocrystal indicated that a BF₄⁻ bound CsPbBr₃ nanocrystal had a more positively charged surface, which was consistent with literatures (FIG. 17). A somewhat contradictory result that the NOBF₄-treated CsPbBr₃ nanocrystal exhibited a positively charged surface, can be understood as a result of a surface reconstruction due to a NO⁺-induced substitution of an original ligand (i.e., Cs-carboxylate). In addition, BF₄⁻ anions are less nucleophilic and basic than halides or nitrates, and belong to Z-type ligands, based on evenly distributed negative charges over four highly electronegative F atoms.

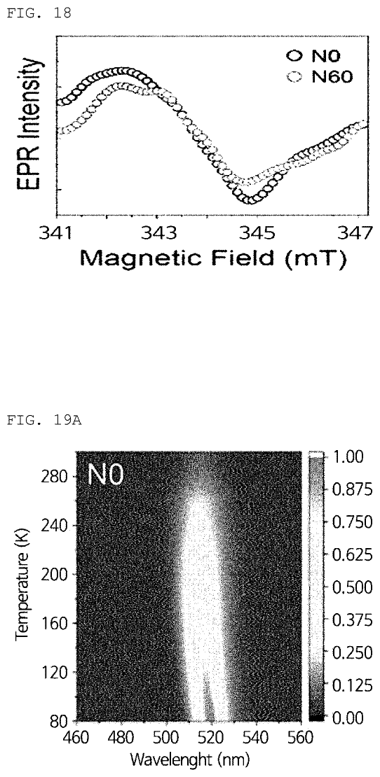

To further investigate defects involved in an ion exchange process with BF₄⁻ anions, electron paramagnetic resonance (EPR) spectroscopy was performed on the solid CsPbBr₃ nanocrystals. Obtained spectra showed a narrow, isotropic linearity characterized by a g value of about 2.001 (FIG. 18). The cesium- and bromine-related centers with nucleospins of I=7/2 and I=3/2 were expected to show eight and four hyperfine cleavages, respectively. Therefore, EPR signals were assumed to originate from a paramagnetic state of either the Pb⁺ center (6p¹ species) or the Pb³⁺ center (6s¹ species). However, since Pb⁺ (6p¹) shows a nearly isotropic g tensor in a range 1-1.7, a detected EPR signal seems to originate from 6s¹ electrons of Pb³⁺ rather than 6p¹ electrons of Pb⁺. Based on a relationship between an integral of an absorption spectrum (i.e., a double integral of the EPR signal) and a spin number, a reduced spin density can be clearly observed in the NOBF₄-treated CsPbBr₃ nanocrystals, which implies that after NOBF₄ treatment, Pb³⁺ defects in the CsPbBr₃ nanocrystals have been reduced. Since Pb4f XPS peaks associated with Pb—O bonds were significantly suppressed in a presence of BF₄⁻ anions, it was assumed that Pb³⁺ defects resulted from a substitution of lattice bromine by oxygen and trapped holes. This could explain an observation that a EPR spin density decreases after NOBF₄ treatment, which is because a density of these oxygen-related defects is expected to decrease when a bromine defect concentration is low.

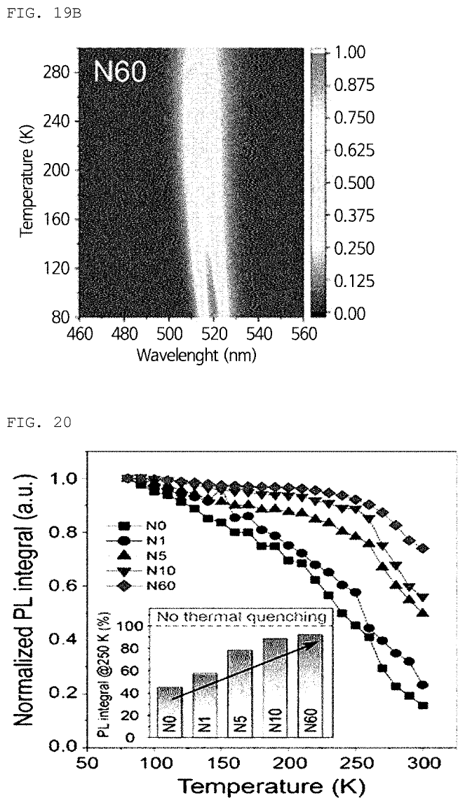

An enhanced PLQY and associated optical properties due to a presence of BF₄⁻ anions on the surface of CsPbBr₃ nanocrystal suggest that unwanted defect trapping, and multicarrier processes such as trapping, or phonon-assisted recombination are successfully reduced. To understand an effect of a presence of BF₄⁻ anions on the surface of CsPbBr₃ nanocrystal on an exciton-phonon interaction and high-energy electron decay kinetics, temperature-dependent photophysical properties of the NOBF₄-treated CsPbBr₃ nanocrystal were investigated using cryogenic PL spectroscopy. FIGS. 19A to 19B show 2D pseudo-color plots of temperature-dependent PL emission spectra of a pristine state (N0) and a NOBF₄-treated CsPbBr₃ nanocrystal (N60), respectively. For both samples, a single peak was observed in PL spectra at all temperatures, with a slight blue shift in a PL peak position along with temperature increase. This shift is attributed to a lattice thermal expansion and an electron-phonon interaction, which serve to reduce strong s-p antibonding interactions of valence orbitals (i.e., Br 4p and Pb 6s orbitals), and consequently decrease a valence band maximum potential energy, thereby increasing a bandgap energy. Thus, this verifies that BF₄⁻ anions are present on a surface of CsPbBr₃ nanocrystal, and not contained in a perovskite lattice.

In particular, a normalized PL area as a function of temperature clearly shows that the NOBF₄-treated CsPbBr₃ nanocrystal exhibits a minimal thermal quenching with increasing NOBF₄ concentration, while a pristine nanocrystal shows a significant PL quenching with increasing temperature (FIG. 20). For example, at T=80 K, the temperature point where a PL intensity integral exceeds 90%, is significantly shifted from 130 K for a pristine sample (NO) to 270 K for a NOBF₄-treated sample (N60). This shift progressed gradually depending on NOBF₄ concentrations, and was observed for N1 (T=160 K), N5 (T=180 K), N10 (T=240 K), and N60 (T=270 K). In particular, the N60 sample exhibited almost no thermal quenching in a temperature range of 80 to 250 K, with a PL intensity integral at T=250 K remaining above 92%, compared to only 45% for the pristine sample (see inset in FIG. 20). When most of carriers generated by light recombine rapidly, phonon-assisted processes become more prominent at relatively high temperatures, promoting non-radiative relaxation such as carrier trapping, exciton dissociation, or carrier escape from localized states. Therefore, these observations clearly suggest that a NOBF₄ treatment effectively inhibits a thermally active non-radiative recombination.

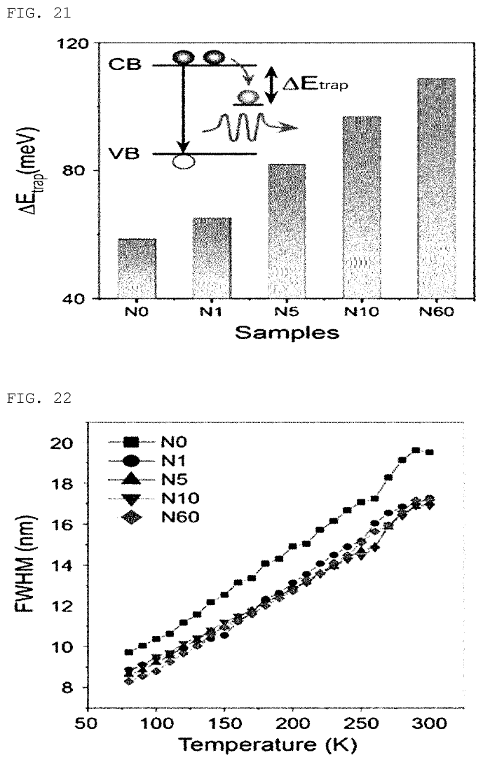

To investigate an exciton localization depth associated with non-radiative decay, activation energy of a carrier trapping (ΔEₜᵣₐₚ) was calculated by fitting an integrated PL intensity and a temperature dependence. The equation used is I(T)=I₀(1+Ae^{-ΔE}^{ₜᵣₐₚ}^{/k}^{_{B}}^{T})⁻¹, wherein I₀ and A denote an integral PL intensity at T=0 K, and a frequency factor associated with a trapped state, respectively. A ΔEₜᵣₐₚ value obtained from a fitting curve is shown in FIG. 21. For a pristine CsPbBr₃ nanocrystal, an activation energy associated with a carrier trapping was determined to be 58.6 meV, which is similar to energies reported for shallow states attributed to metallic Pb⁰ And bromine defects. A typical PL quenching process involving transitions between intrinsic states and shallow defect states was reported to have an activation energy of about 57.4 meV. In contrast, the NOBF₄-treated nanocrystal showed a significant increase in the ΔEₜᵣₐₚ value, reaching about 108.8 meV, indicating that the surface defects associated with the shallow state are less likely to decompose excitons into free carriers when the surface defects bind to BF₄⁻ molecules.

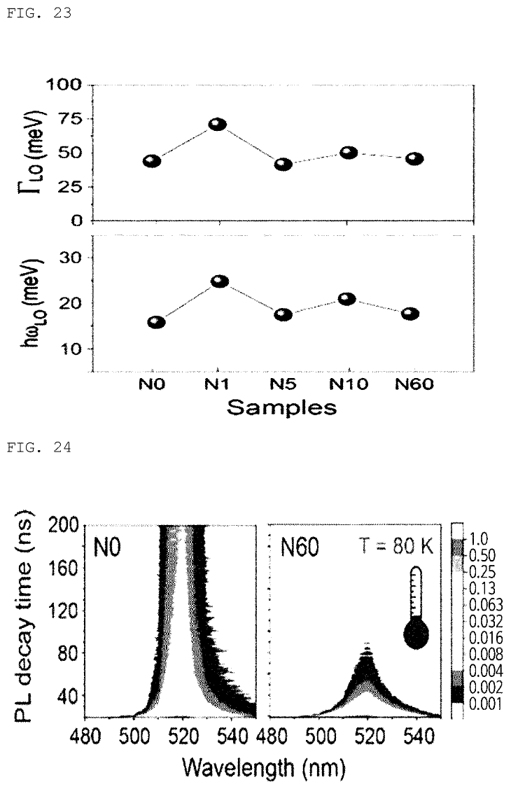

When a temperature increased from 80 K to 300 K, a broadening of a FWHM of PL spectra of the CsPbBr₃ nanocrystal was observed due to exciton scattering by acoustic and longitudinal optical (LO) phonons (FIG. 22). A temperature dependence of an emission bandwidth can be explained by a Boson model, which is given by equation Γ(T)=Γᵢₙₕ+Γ_{AC}T+Γ_{LO}(e^{hω}^{_{LO}}^{/k}^{_{B}}^{T}−1)⁻¹, wherein Γᵢₙₕ represents an inhomogeneous broadening resulting from scattering processes associated with variations in crystal size, shape, and composition, and lattice imperfections. Γ_{AC} is an exciton-acoustic phonon coupling coefficient, k_{B} is a Boltzmann constant, and Γ_{LO} and h_{ωLO} are an exciton-LO phonon coupling coefficient and LO phonon energy, respectively. Since an LO phonon can be explained based on a cross-vibration of lead and bromine atoms in the [PbBr₆]₄-octahedral unit, a lattice discontinuity on a surface plays an important role in determining an LO phonon energy (i.e., h_{ωLO}). However, the values of h_{ωLO} and Γ_{LO} extracted from the CsPbBr₃ nanocrystal after NOBF₄ treatment did not show significant differences, suggesting that NOBF₄ treatment is effective in suppressing thermally activated shallow traps rather than exciton-LO phonon coupling (FIG. 23, Table 4).

TABLE 4

| | Γᵢₙₕ (meV) | Γ_{AC} (meV) | Γ_{LO} (meV) | ℏω_{LO} (meV) |
|---|---|---|---|---|
| N0 | 39.325 | 0.003 | 43.998 | 15.801 |
| N1 | 38.248 | 0.003 | 70.915 | 24.803 |
| NN5 | 36.028 | 0.003 | 41.534 | 17.460 |
| N10 | 38.536 | 0.003 | 50.221 | 20.939 |
| N60 | 34.002 | 0.003 | 45.674 | 17.691 |

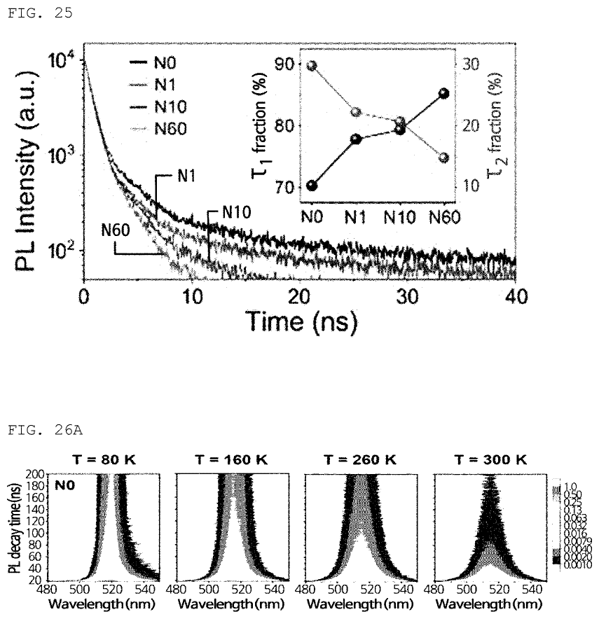

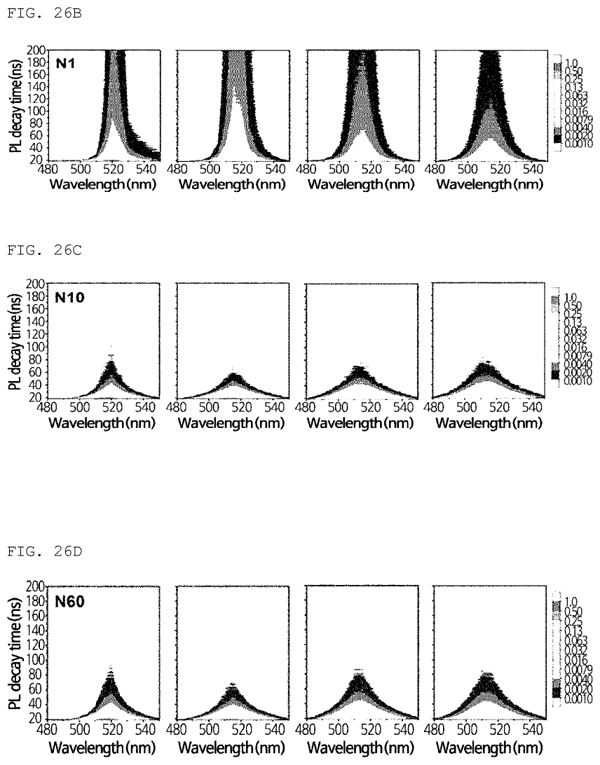

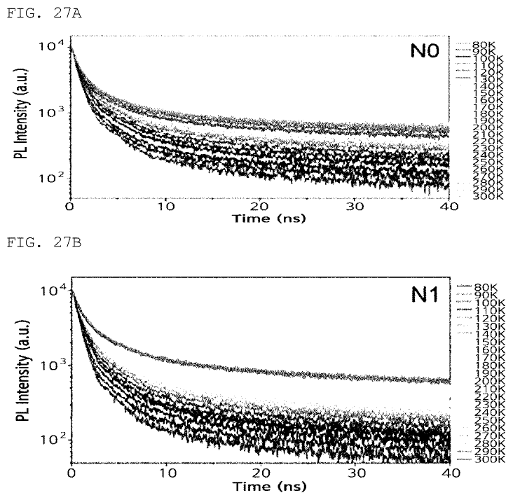

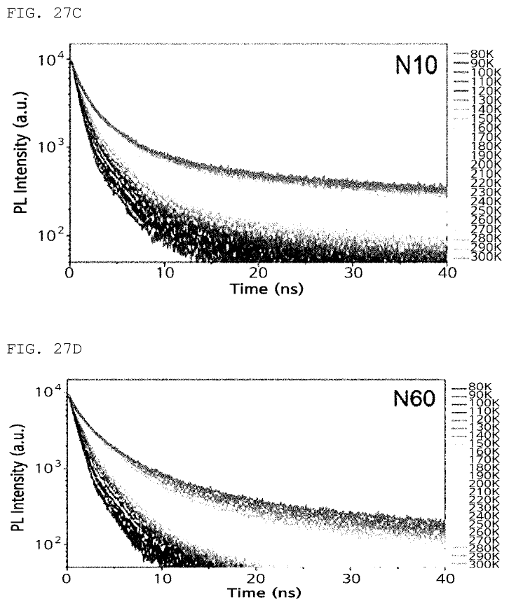

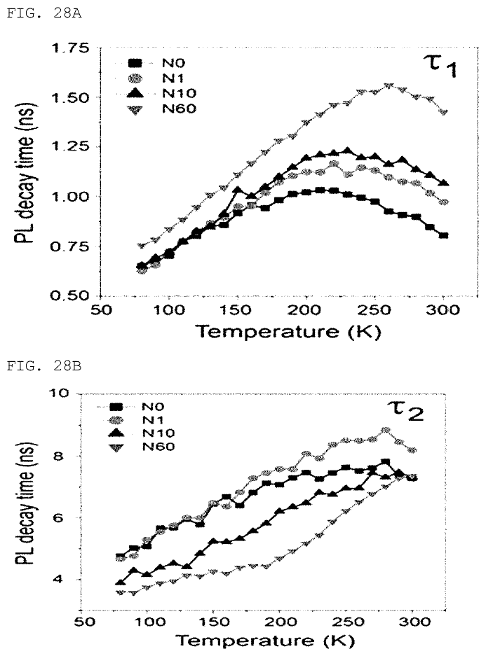

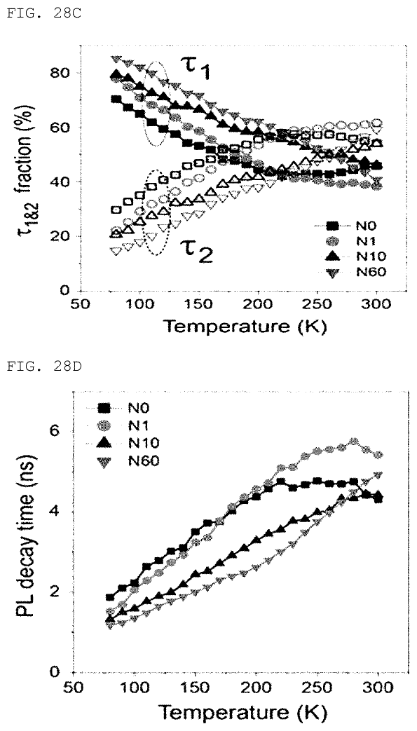

In this regard, a time-resolved emission spectroscopy (TRES) and Urbach energy data support a role of NOBF₄ treatment in suppressing shallow traps in the CsPbBr₃ nanocrystal. Temperature-dependent PL decay spectra in 480-550 nm range, and PL decay curves as a function of a NOBF₄ concentration are shown in FIGS. 24 to 28. A temperature dependence of an fast radioactive decay component (τ₁) and a long radioactive decay component (τ₂) showed that a τ₁ fraction (f1), which corresponds to a radioactive recombination of ground state excitons, increases, while a τ₂ fraction (f2), which is related to a thermally activated trap process, decreases at lower temperatures. With an increase in the NOBF₄ concentration, the long radioactive decay component (τ₂) decreased significantly, indicating that a trap pathway was significantly inhibited (c in FIGS. 28A to 28D).

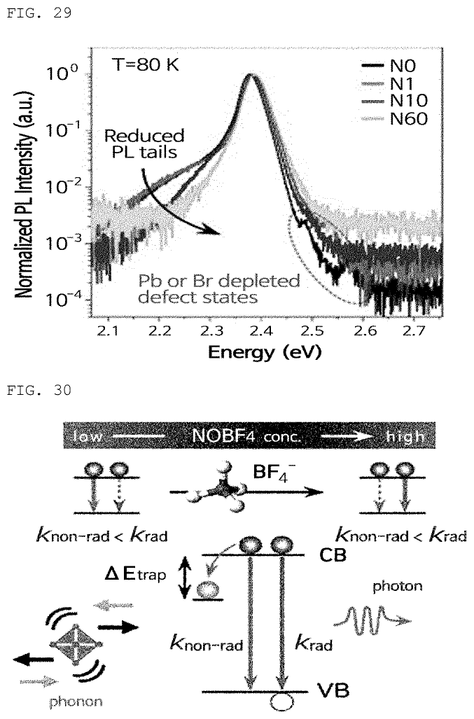

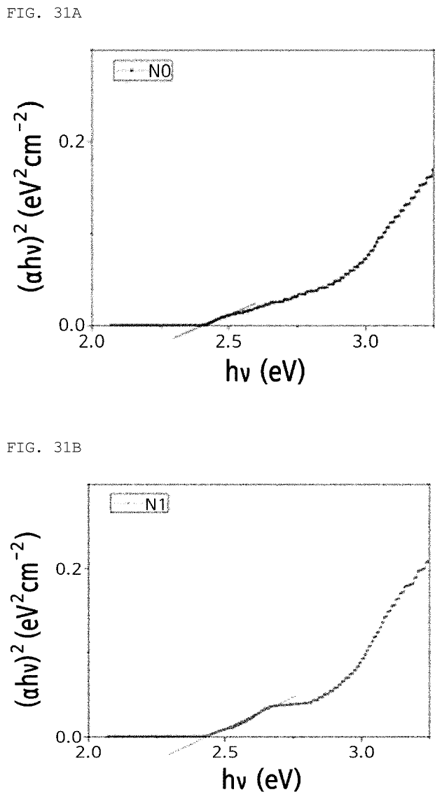

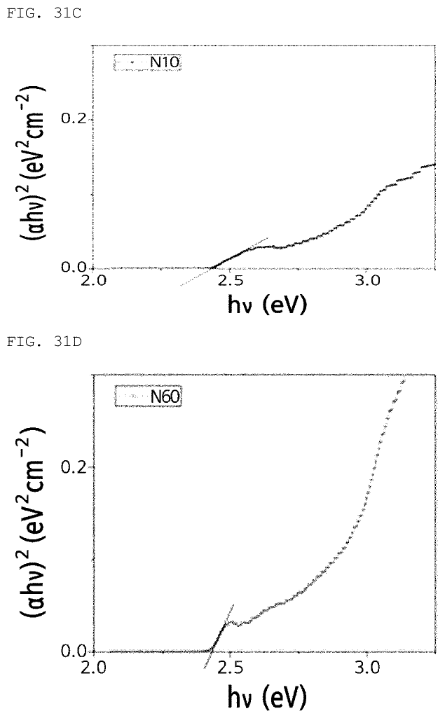

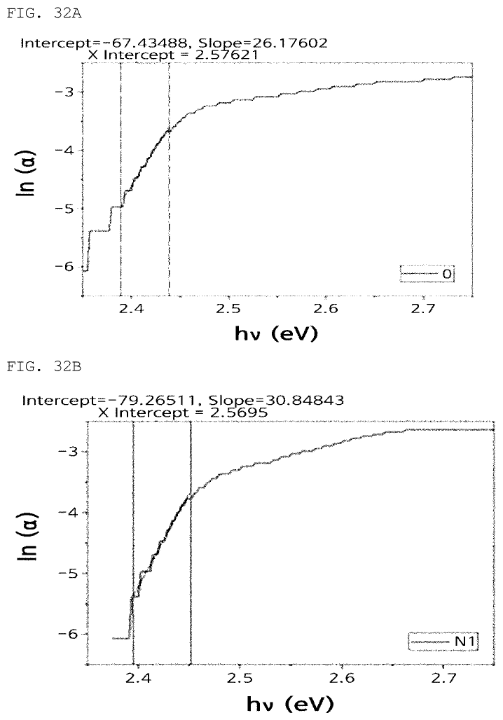

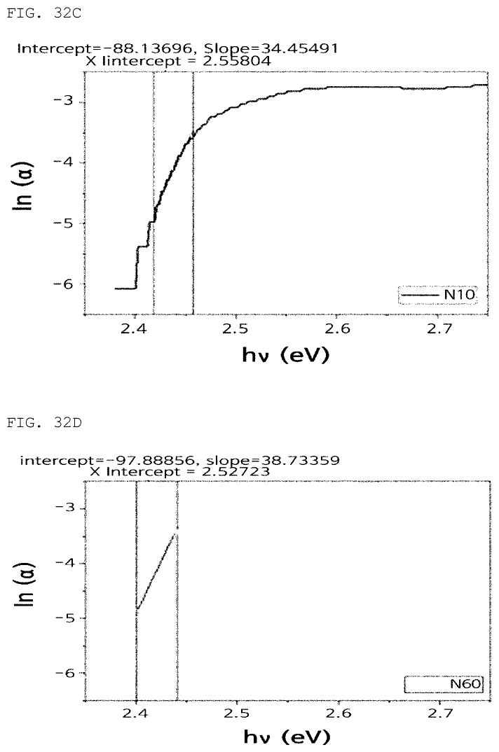

In addition, high-energy shoulder peaks and low-energy tails of PL emission spectra associated with carriers bound to structural inhomogeneities and defects were progressively reduced with NOBF₄ treatments (N1 to N60) (FIG. 29). These results confirm that a thermally active trapping process associated with a non-radiative recombination (knon-rad) was successfully suppressed in a presence of BF₄⁻ anions on a surface of CsPbBr₃ nanocrystal (FIG. 30). This is further supported by a decrease in an Urbach energy, which explains an area of a density of states at band edges. Values of an Urbach energy were measured to be 38.2 meV (N0), 32.4 meV (N1), 29.0 meV (N10), and 25.8 meV (N60), respectively (FIGS. 31 and 32). Overall, these findings suggest that a NOBF₄ treatment enhances optoelectronic properties of the CsPbBr₃ nanocrystal by reducing a presence of shallow traps, which is favorable for a realization of highly efficient and stable CsPbBr₃ LEDs.

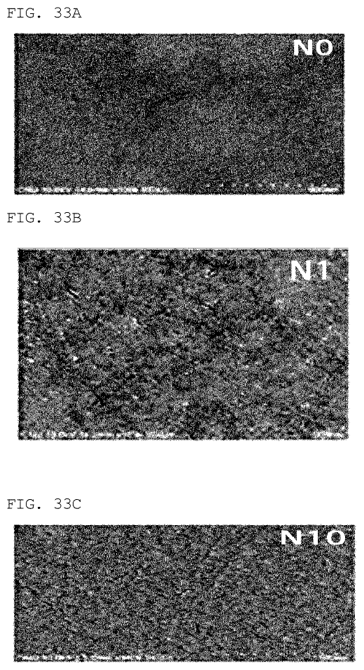

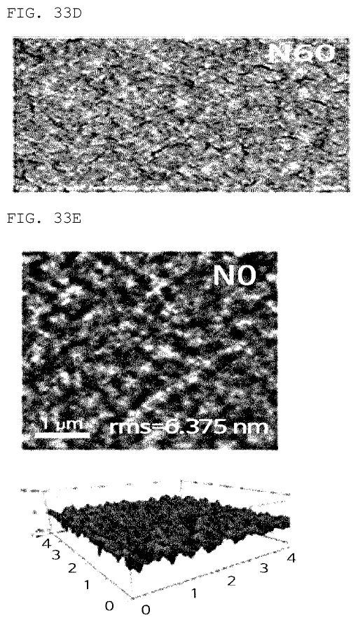

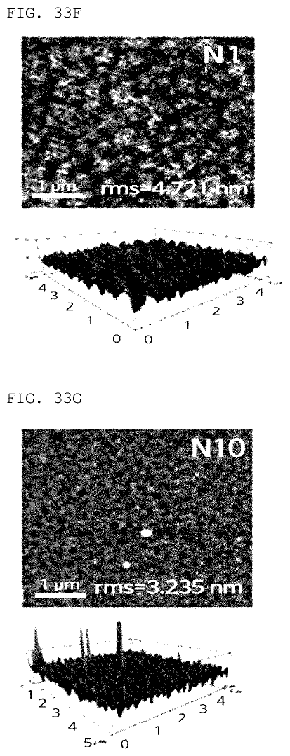

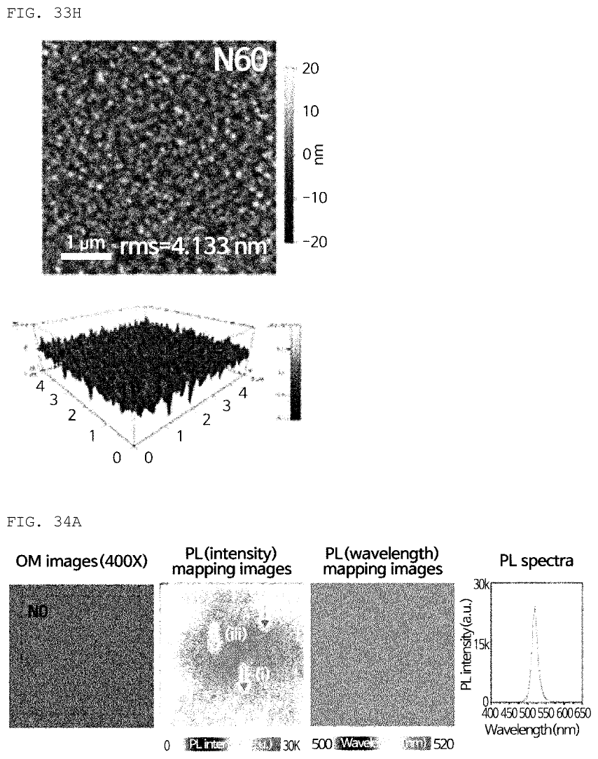

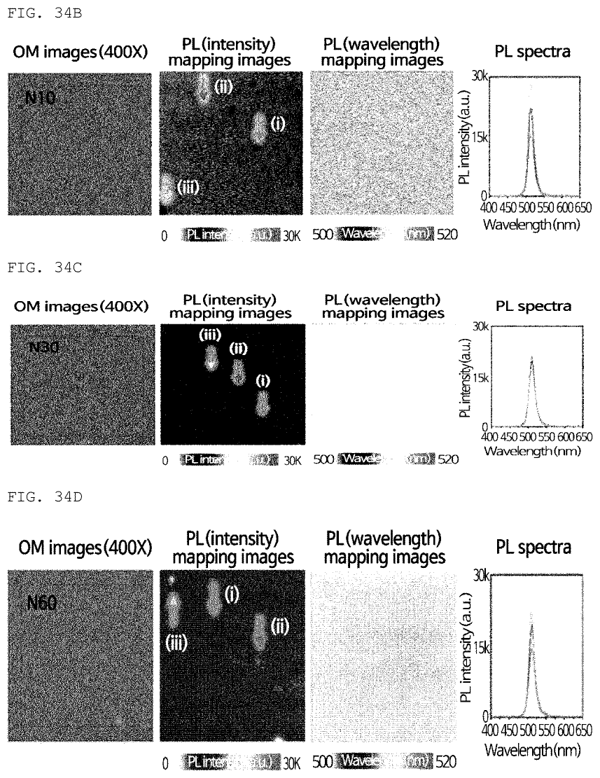

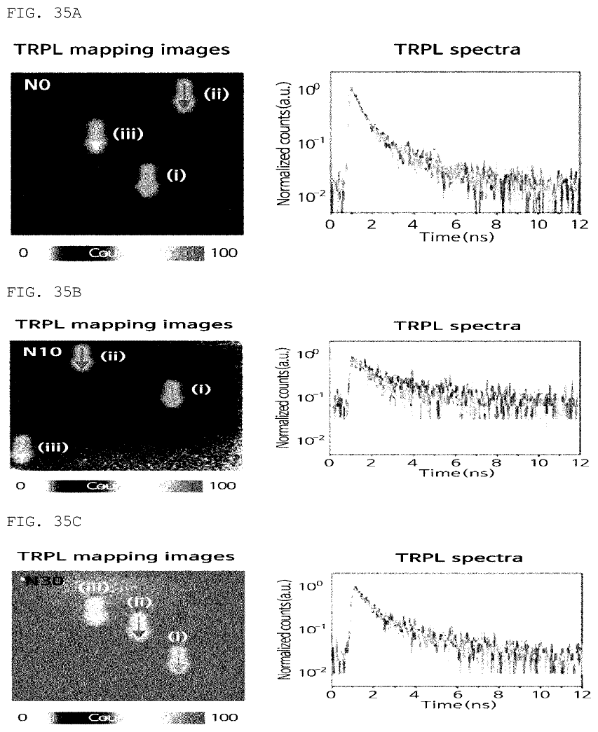

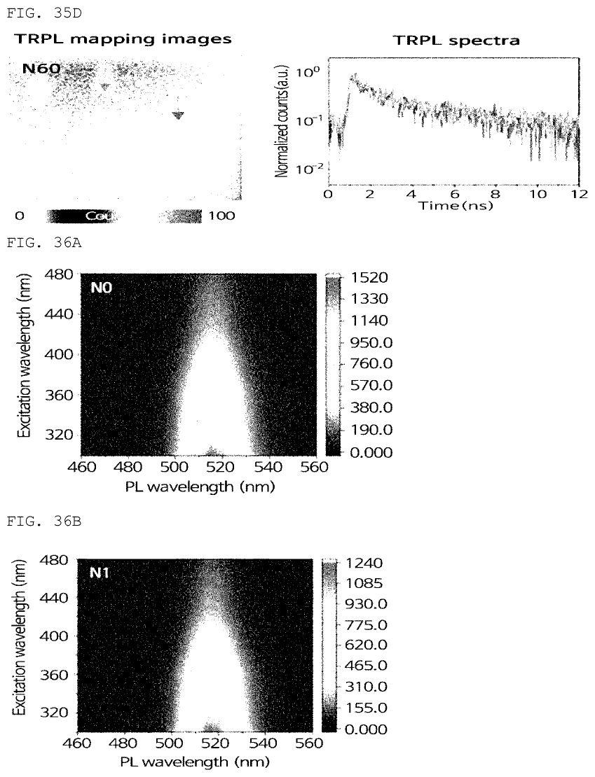

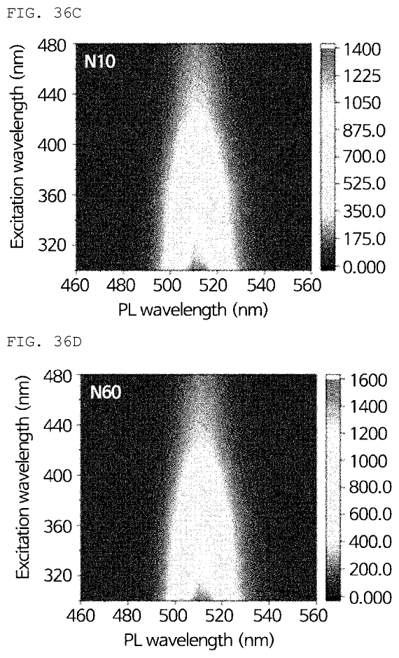

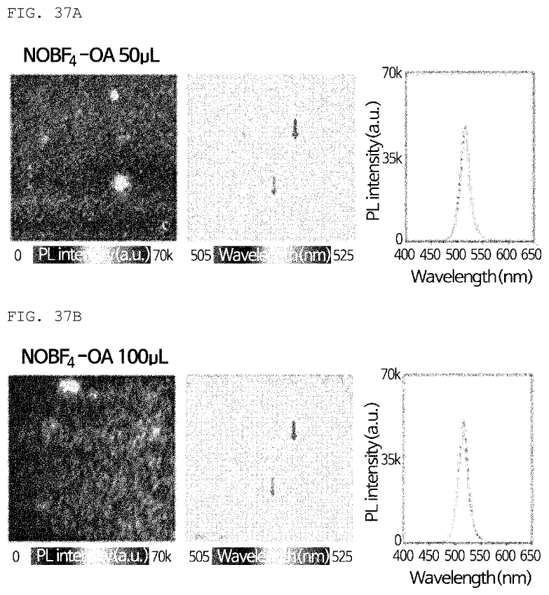

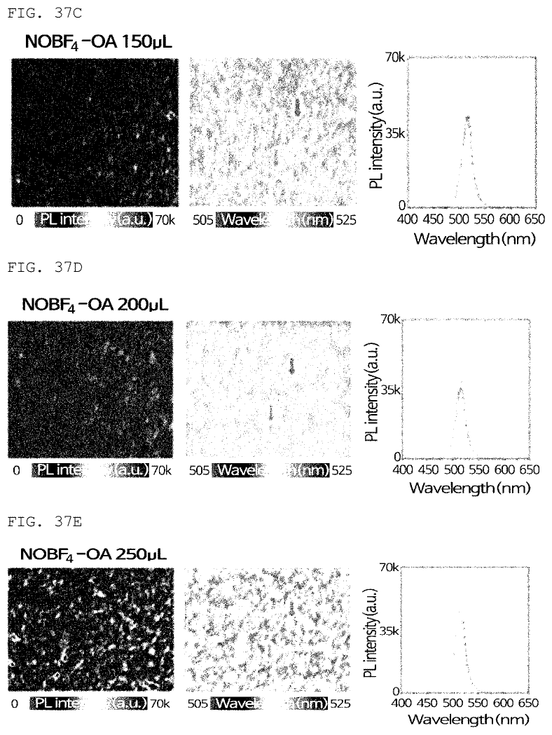

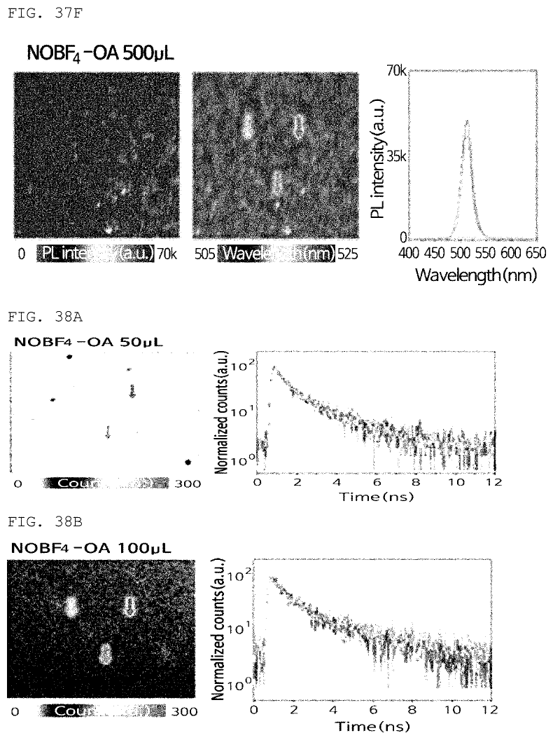

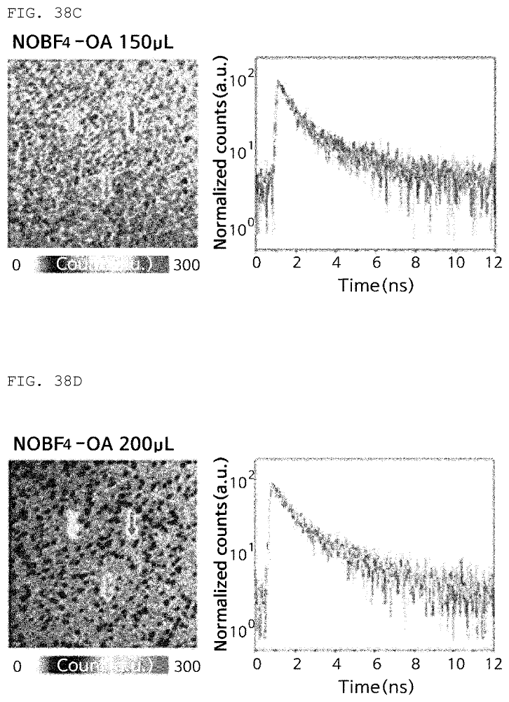

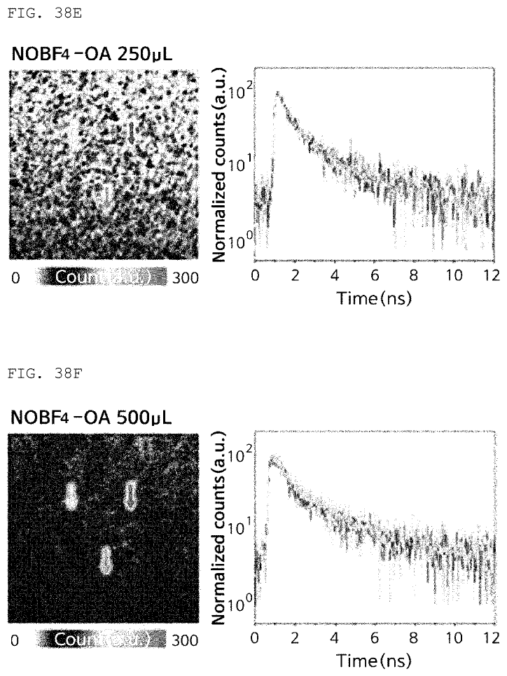

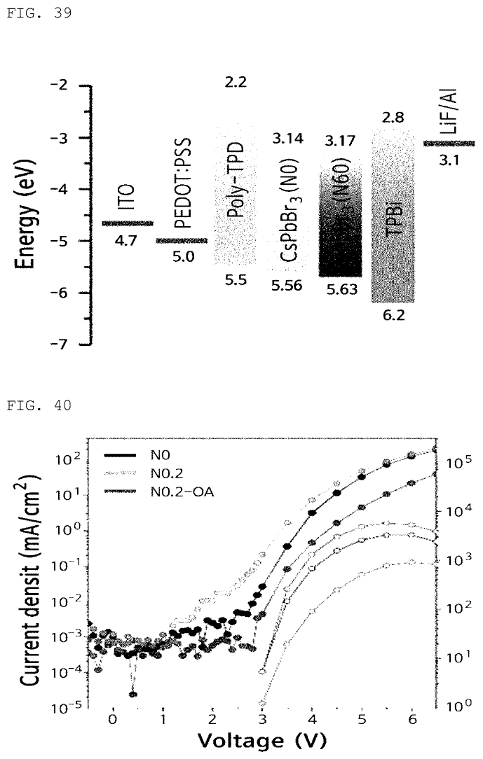

Scanning electron microscopy (SEM), atomic force microscopy (AFM), and PL mapping images were obtained to investigate optical properties related to a surface morphology of CsPbBr₃ nanocrystal films resulting from NOBF₄ treatment (FIGS. 33 to 38). The NOBF₄ treatment caused a formation of cracks in the CsPbBr₃ nanocrystal films due to a decrease in organic ligand content (FIGS. 33A to 33D). Nevertheless, AFM images showed that a root mean square of a surface roughness (Rq=about 3.235-4.721 nm) of the NOBF₄-treated CsPbBr₃ nanocrystal films (N1-N60) was significantly reduced compared to that of a pristine film (N0, Rq=about 6.375 nm) (FIGS. 33E to 33H). In particular, an irregular valley-like surface caused by an aggregation of the nanocrystals with excess ligands was alleviated by NOBF₄ treatment. PL and TRPL mapping images confirmed an uniform PL emission and lifetime of the CsPbBr₃ nanocrystal films regardless of whether NOBF₄ treatment was performed or not (FIGS. 34 to 38).

Energy levels of a pristine nanocrystal and the NOBF₄-treated CsPbBr₃ nanocrystals were measured by an ultraviolet photoelectron spectroscopy (UPS) (Table 5).

TABLE 5

| | E_{cut-off} | LOW E tail | E_{VBM} | E_{CBM} | E_{g} | E_{F} |
|---|---|---|---|---|---|---|
| | (eV) | (eV) | (eV) | (eV) | (eV) | (eV) |
| N0 | 17.681 | 2.021 | 5.560 | 3.144 | 2.416 | 3.539 |
| N60 | 17.020 | 1.428 | 5.628 | 3.166 | 2.462 | 4.200 |

Values of Fermi levels (E_{Fermi}), a top valence band (EVBM), and a conduction band minimum (E_{CBM}) before and after NOBF₄ treatment were determined using a cutoff energy, an onset energy, and an optical bandgap energy. The E_{Fermi} values of a pristine (NO) and the NOBF₄-treated (N60) CsPbBr₃ nanocrystals were estimated to be 3.54 eV and 4.2 eV, respectively. The downward shift of an E_{Fermi} indicates a decrease in an electron density due to an escape of electrons from BF₄⁻ anions. The EVBM and ECBM values of the NOBF₄-treated CsPbBr₃ nanocrystal (N60) were slightly lower than those of the pristine CsPbBr₃ nanocrystal (N0) (FIG. 39).

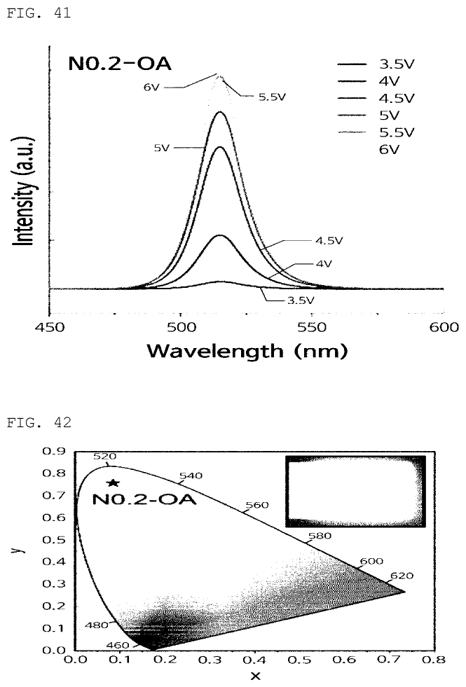

Next, a performance of green-emitting perovskite LEDs (PeLEDs) devices with a typical structure consisting of a patterned ITO anode, a PEDOT:PSS (30 nm) film, a poly-TPD (10 nm) film, a CsPbBr₃ nanocrystal film (50 nm), a TPBi (55 nm) film, and a LiF/Al cathode (ITO/PEDOT:PSS/poly-TPD/CsPbBr₃/TPBi/LiF/Al) was evaluated. First, a CsPbBr₃ nanocrystal (N0.2) with a significantly reduced amount of NOBF₄ were used to prevent unexpected reactions of residual NO⁺ cations acting as oxidants, and to prevent a formation of NO₂ molecules. PeLEDs based on the NOBF₄-treated CsPbBr₃ nanocrystal (N0.2) exhibited about 1.73 times higher luminance (5684 cd/m²), and about five times higher current density than those of pristine PeLEDs, indicating that a ligand exchange of long alkyl chains with short BF₄⁻ anions reduced a charge injection barrier (FIG. 40). This resulted in NOBF₄-treated CsPbBr₃ PeLEDs achieving an EQE enhancement of 6.04%, about 1.5 times higher than that of pristine PeLEDs (EQE=4.06%). However, when a NOBF₄ concentration exceeds N0.2, a luminance of the NOBF₄-treated CsPbBr₃ PeLEDs decreased drastically despite similar I-V characteristics. To mitigate this side reaction, residual NO⁺ cations were removed by reacting with OA, resulting in effectively binding of mobile NO⁺ cations to carboxyl groups of OA. As a result, a device performance of the CsPbBr₃ nanocrystal treated with NOBF₄—OA mixture (N0.2-OA) was significantly improved.

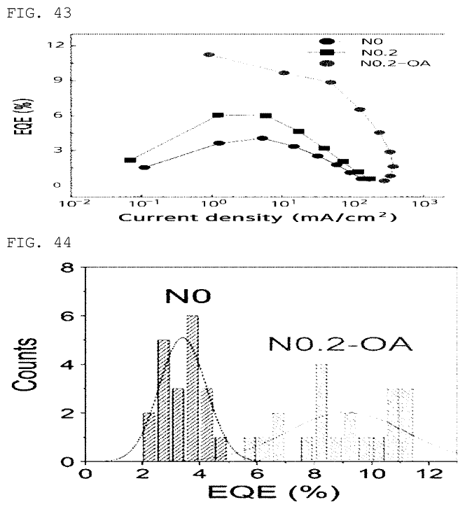

An electroluminescence (EL) spectra of NOBF₄-treated CsPbBr₃ PeLEDs (N0.2-OA) operating at different voltages (3.5-6.0 V) exhibited an emission peak at 515 nm (FIG. 41). Corresponding International Commission on Illumination (CIE) chromaticity coordinates (0.085 and 0.758) were obtained from an uniform EL emission of a PeLEDs (N0.2-OA) operating at 5 V (FIG. 42). When a NOBF₄—OA mixture was adopted for a NOBF₄-treated CsPbBr₃ PeLEDs (N0.2-OA), an EQE was further increased to 11.24%, but current density and luminance decreased (FIGS. 40 and 43). This is attributed to a balanced injection of electrons and holes into an emission layer. Hole-only and electron-only devices were fabricated as ITO/PEDOT: PSS (30 nm)/poly-TPD (10 nm)/CsPbBr₃ nanocrystal film (50 nm)/MoO₃ (5 nm)/Ag (60 nm) structure (hole-only), and ITO/TPBi (40 nm)/CsPbBr₃ nanocrystal film (50 nm)/TPBi (55 nm)/LiF (2 nm)/Al (80 nm) structure (electron-only). Then, carrier mobility and trap density were estimated by measuring a space charge-limited current (SCLC) in hole- and electron-only devices.

The trap density was calculated using a following equation:

$${n}_{t ( e / h )} = 2 {εε}_{0} {V}_{TFL ( e / h )} / {( ed )}^{2} ,$$

wherein nₜ, ε, ε₀, VTFL, e, and d are a trap state density, a relative permittivity, a vacuum permittivity, a trap filling limit voltage, a base charge, and an inter-electrode distance, respectively. The carrier mobility was evaluated in a Child region according to a Mott-Gurney equation:

$${μ}_{( e / h )} = ( 8 {J}_{D} {d}^{3} ) / ( 9 {εε}_{0} {V}^{2} ) ,$$

wherein μ and J_{D} denote carrier mobility and dark current density, respectively. The carrier trap state density and mobility are listed in Table 6.

TABLE 6

| | | | | | Mobility | Mobility |
|---|---|---|---|---|---|---|
| | V_{TFL(e)} | V_{TFL(h)} | n_{t (e)} | n_{t (h)} | (e) | (h) |
| | (V) | (V) | (cm⁻³) | (cm⁻³) | (cm²/Vs) | (cm²/Vs) |
| N0 | 1.037 | 0.749 | 2.62 × | 4.91 × | 4.38 × | 2.69 × |
| | | | 10¹⁶ | 10¹⁶ | 10⁻⁵ | 10⁻⁴ |
| N0.2 | 0.969 | 0.769 | 2.45 × | 5.04 × | 4.13 × | 2.99 × |
| | | | 10¹⁶ | 10¹⁶ | 10⁻⁵ | 10⁻⁴ |
| N0.2- | 1.011 | 0.861 | 2.55 × | 5.64 × | 6.68 × | 2.02 × |
| OA | | | 10¹⁶ | 10¹⁶ | 10⁻⁵ | 10⁻⁴ |

After a NOBF₄ treatment, electron-only devices didn't show significant differences in trap fill voltage (VTFL), while hole-only devices showed an increase in V_{TFL} value, resulting in an increase in trap state density from 4.91×10¹⁶ (N0) to 5.64×10¹⁶ cm⁻³ (N0.2-OA). These results suggest that a hole transport behavior plays a major role in the NOBF₄-treated CsPbBr₃ LEDs, leading to a more balanced charge injection, and higher EQE (FIG. 43). A reproducibility of pristine and NOBF₄-treated CsPbBr₃ PeLEDs (N0.2-OA) is shown in a histogram obtained by measuring 20 devices (FIG. 44).

These results clearly show that the NOBF₄ treatment improves the radiative recombination of charge carriers, and reduces thermal quenching by eliminating shallow states associated with surface defects without lowering a charge transfer efficiency due to insulating ligands. These results demonstrate that a charge carrier trapping on the surface of a CsPbBr₃ nanocrystal is suppressed, thereby improving a charge injection efficiency.

While the present disclosure has been described with the above specific details and limited embodiments, which are provided for a more general understanding of the present disclosure, the present disclosure is not limited to the above embodiments, and various modifications and variations can be made from these descriptions by those having ordinary knowledge in the field to which the present disclosure belongs.

Accordingly, the ideas of the present disclosure are not to be limited to the embodiments described, and it will be understood that all modifications and equivalents thereof, as well as the claims of the following patent, fall within the scope of the present disclosure.

What is claimed is:

1. A defect-free perovskite nanocrystal, comprising CsPbX₃ (wherein X is a halogen) perovskite nanocrystal whose surface is modified with BF₄⁻ anions.

2. The defect-free perovskite nanocrystal of claim 1, wherein the defect-free perovskite nanocrystal is characterized by having a space group Pbnm which is found in the X-ray diffraction (XRD) pattern, and satisfying the following equations 1 to 3:
$$8.1 \leq a \leq 8.3 Å \qquad [ Equation 1 ]$$
$$8.15 \leq b \leq 8.35 Å \qquad [ Equation 2 ]$$
$$11.6 \leq c \leq 11.9 Å , \qquad [ Equation 3 ]$$
wherein in the Equations 1 through 3,
a, b, and c each represent a lattice constant of the defect-free perovskite nanocrystalline structure which is obtained in an X-ray diffraction (XRD) pattern, provided that a is a lattice constant representing a length along an a-axis, b is a lattice constant representing a length along a b-axis, and c is a lattice constant representing a length along a c-axis.

3. The defect-free perovskite nanocrystal of claim 1, wherein the defect-free perovskite nanocrystal displays a photoluminescence peak in a 480 to 550 nm wavelength region of a photoluminescence (PL) spectrum.

4. The defect-free perovskite nanocrystal of claim 1, wherein the defect-free perovskite nanocrystal has an average size of 1 to 50 nm.

5. The defect-free perovskite nanocrystal of claim 1, wherein the BF₄⁻ anion surface-modified CsPbX₃ (wherein X is a halogen) perovskite nanocrystal is CsPbX₃ (wherein X is a halogen) perovskite nanocrystal treated with nitrosonium tetrafluoroborate (NOBF₄).

6. A method of manufacturing a defect-free perovskite nanocrystal, the method comprising:
a) preparing a CsPbX₃ (wherein X is a halogen) perovskite nanocrystal; and
b) surface-treating the nanocrystal solution by adding a solution of nitrosonium tetrafluoroborate (NOBF₄).

7. The method of claim 6, wherein the CsPbX₃ (wherein X is a halogen) perovskite nanocrystal is prepared by:
(i) preparing a precursor solution comprising PbX₂ (wherein X is a halogen), a fatty acid, and a fatty amine; and
(ii) preparing the perovskite nanocrystal by mixing cesium oleate in the precursor solution.

8. The method of claim 6, wherein the fatty acid is one or more selected from a group consisting of oleic acid, palmitoleic acid, vaccenic acid, and paullinic acid.

9. The method of claim 6, wherein the fatty amine is one or more selected from a group consisting of hexylamine, octylamine, decylamine, dodecylamine, and oleylamine.

10. The method of claim 7, wherein the cesium oleate is added in an amount of 0.01 to 1 ml per 1 ml of the precursor solution.

11. A light-emitting device comprising the defect-free perovskite nanocrystal of claim 1.

12. A light-emitting device comprising the defect-free perovskite nanocrystal of claim 2.

13. A light-emitting device comprising the defect-free perovskite nanocrystal of claim 3.

14. A light-emitting device comprising the defect-free perovskite nanocrystal of claim 4.

15. A light-emitting device comprising the defect-free perovskite nanocrystal of claim 5.
